(19) United States
(12) Patent Application Publication
(10) Pub. No.: US 2026/0101653 A1
(43) Pub. Date: Apr. 9, 2026

(54) DISPLAY PANEL AND DISPLAY DEVICE

(71) Applicants: Chengdu BOE Optoelectronics Technology Co., Ltd., Sichuan (CN); BOE TECHNOLOGY GROUP CO., LTD., Beijing (CN)

(72) Inventors: Yixuan LONG, Beijing (CN); Tinghua SHANG, Beijing (CN); Jiaxing CHEN, Beijing (CN); Biao LIU, Beijing (CN); Zuoji NIU, Beijing (CN); Peng XU, Beijing (CN); Yi ZHANG, Beijing (CN); Yan HUANG, Beijing (CN); Qian XU, Beijing (CN)

(21) Appl. No.: 19/114,850

(22) PCT Filed: Apr. 28, 2023
(86) PCT No.: PCT/CN2023/091699

§ 371 Date: Mar. 25, 2025

(51) Int. Cl. H10K 59/131; H10K 59/121

(52) U.S. Cl. CPC H10K 59/1315; H10K 59/1213; H10K 59/1216

(57) ABSTRACT

A display panel, includes: a base substrate; a plurality of first signal lines, where orthographic projections of the plurality of first signal lines on the base substrate extend in a first direction and are distributed at intervals in a second direction, and the first direction intersects with the second direction; a plurality of first signal connection lines, where an orthographic projection of a first bridging portion on the base substrate is located between orthographic projections of two first signal connection lines adjacent in the first direction on the base substrate, and the orthographic projection of the first bridging portion on the base substrate is located between orthographic projections of two adjacent first signal lines on the base substrate.

### CROSS REFERENCE TO RELATED APPLICATIONS

The present application is a U.S. national stage of International Application No. PCT/CN2023/091699, filed on Apr. 28, 2023, and the entire contents of which are incorporated herein by reference.

### TECHNICAL FIELD

The present disclosure relates to the field of display technologies, and in particular, to a display panel and a display device.

### BACKGROUND

In the related art, there is a voltage drop of the signal on the signal line in the display panel, resulting in uneven display of the display panel.

It should be noted that the information disclosed in the above background part is only configured to enhance the understanding of the background of the present disclosure, and therefore may include information that does not constitute the related art known to those of ordinary skill in the art.

### SUMMARY

According to an aspect of the present disclosure, there is provided a display panel, where the display panel includes: a base substrate, a plurality of first signal lines, a plurality of first signal connection lines, a plurality of second signal lines, and a plurality of first bridging portions. Orthographic projections of the plurality of first signal lines on the base substrate extend in a first direction and are distributed at intervals in a second direction, and the first direction intersects with the second direction. An orthographic projection of a first signal connection line on the base substrate extends in the second direction, and the first signal connection line is connected between two first signal lines adjacent in the second direction to form a grid structure with the first signal lines. The second signal lines are located in a different conductive layer from the first signal lines, and orthographic projections of the plurality of second signal lines on the base substrate extend in the second direction and are distributed at intervals in the first direction. A first bridging portion is connected between two second signal lines adjacent in the first direction to form a grid structure with the second signal lines; where an orthographic projection of the first bridging portion on the base substrate is located between orthographic projections of two first signal connection lines adjacent in the first direction on the base substrate, and the orthographic projection of the first bridging portion on the base substrate is located between orthographic projections of two adjacent first signal lines on the base substrate.

In some embodiments of the present disclosure, two adjacent first signal connection lines and two adjacent first signal lines connected to the two adjacent first signal connection lines form an annular structure, and a plurality of annular structures include a first annular structure, a second annular structure, and a third annular structure; the first annular structure and the second annular structure are distributed in the first direction, the first annular structure and the third annular structure are distributed in the second direction, and the first annular structure and the third annular structure are provided in a staggered manner in the first direction; the second annular structure and the third annular structure are distributed in the second direction, and the second annular structure and the third annular structure are provided in a staggered manner in the first direction; the first bridging portion whose orthographic projection on the base substrate being located within one of the annular structures forms a bridging portion group; a plurality of bridging portion groups includes a first bridging portion group, a second bridging portion group, and a third bridging portion group; an orthographic projection of the first bridging portion group on the base substrate is located within an orthographic projection of the first annular structure on the base substrate, an orthographic projection of the second bridging portion group on the base substrate is located within an orthographic projection of the second annular structure on the base substrate, and an orthographic projection of the third bridging portion group on the base substrate is located within an orthographic projection of the third annular structure on the base substrate; and, the first bridging portion group and the second bridging portion group are respectively connected to different second signal lines, the first bridging portion group and the third bridging portion group are connected to at least one same second signal line, and the second bridging portion group and the third bridging portion group are connected to at least one same second signal line.

In some embodiments of the present disclosure, the first annular structure and the second annular structure share a same first signal connection line, the first annular structure and the third annular structure share a partial structure of a same first signal line, and the second annular structure and the third annular structure share a partial structure of a same first signal line.

In some embodiments of the present disclosure, the first bridging portions located between two adjacent first signal lines in a same group are provided at intervals in the first direction; and, a distance in the first direction between orthographic projections of two first signal connection lines in each of the annular structures on the base substrate is the same or approximately the same, and each bridging portion group includes a same quantity of first bridging portions.

In some embodiments of the present disclosure, a first bridging portion in the first bridging portion group includes a first bridging sub-portion, a first bridging portion in the second bridging portion group includes a second bridging sub-portion, and a first bridging portion in the third bridging portion group includes a third bridging sub-portion; in the first direction, an orthographic projection of the third bridging sub-portion on the base substrate is located between an orthographic projection of the first bridging sub-portion on the base substrate and an orthographic projection of the second bridging sub-portion on the base substrate; and, the orthographic projection of the first bridging sub-portion on the base substrate and the orthographic projection of the second bridging sub-portion on the base substrate are provided adjacent in the first direction, and an orthographic projection of the first signal connection line on the base substrate is located between the orthographic projection of the first bridging sub-portion on the base substrate and the orthographic projection of the second bridging sub-portion on the base substrate.

In some embodiments of the present disclosure, the bridging portion group includes a first bridging portion, the first signal connection lines connected between adjacent first signal lines in a same group form a first signal connection line row, and the first bridging portions located between the adjacent first signal lines in a same group form a first bridging portion row; in first signal connection line rows adjacent in the second direction, orthographic projections of the first signal connection lines located in different first signal connection line rows on the base substrate are sequentially and alternately distributed in the first direction; and, in first bridging portion rows adjacent in the second direction, orthographic projections of the first bridging portions located in different first bridging portions rows on the base substrate are sequentially and alternately distributed in the first direction.

In some embodiments of the present disclosure, orthographic projections of the first signal connection lines located in a same first signal connection line row on the base substrate are distributed at equal intervals or approximately equal intervals in the first direction; and, orthographic projections of the first bridging portions located in a same first bridging portion row on the base substrate are distributed at equal intervals or approximately equal intervals in the first direction.

In some embodiments of the present disclosure, the display panel includes a light-emitting unit, a power line, and pixel driving circuits distributed in an array in the first direction and the second direction; a pixel driving circuit is connected to a first electrode of the light-emitting unit, the power line is configured to provide a high-level power signal to the pixel driving circuit, the second direction is a column direction, and each column of pixel driving circuits is correspondingly provided with a power line. The display panel further includes an electrode layer and a pixel definition layer; the electrode layer is located on a side of the base substrate, the electrode layer includes a plurality of electrode portions, and an electrode portion is configured to form a first electrode of the light-emitting unit; the pixel definition layer is located on a side of the electrode layer away from the base substrate, a plurality of pixel openings are formed on the pixel definition layer, the pixel openings and the electrode portions are correspondingly provided, and an orthographic projection of a pixel opening on the base substrate coincides with an orthographic projection of an electrode portion corresponding to the pixel opening on the base substrate; the plurality of electrode portions include a first electrode portion, a second electrode portion, a third electrode portion and a fourth electrode portion; in a plurality of electrode portions connected to a same row of pixel driving circuits, the first electrode portion, the second electrode portion, the third electrode portion and the fourth electrode portion are sequentially and alternately distributed in a row direction; an orthographic projection of the power line on the base substrate extends in the second direction; in adjacent power lines, a power line corresponding to a pixel driving circuit connected to the first electrode portion is connected to a power line corresponding to a pixel driving circuit connected to the fourth electrode portion to form a second signal line; a power line corresponding to a pixel driving circuit connected to the second electrode portion is connected to a power line corresponding to a pixel driving circuit connected to the third electrode portion to form a second signal line; and, the pixel driving circuit connected to the first electrode portion is correspondingly provided with a first signal connection line, the pixel driving circuit connected to the third electrode portion and the fourth electrode portion is correspondingly provided with a first bridging portion, and the first bridging portion is connected between two power lines in the pixel driving circuit corresponding to the first bridging portion.

In some embodiments of the present disclosure, the first electrode portion is configured to form a first electrode of a red light-emitting unit, the second electrode portion and the fourth electrode portion are configured to form a first electrode of a green light-emitting unit, and the third electrode portion is configured to form a first electrode of a blue light-emitting unit.

In some embodiments of the present disclosure, the display panel further includes a data line, an orthographic projection of the data line on the base substrate extends in the second direction, and the data line is configured to provide a data signal to the pixel driving circuit; in the pixel driving circuit and the first signal connection line that are provided correspondingly, an orthographic projection of the first signal connection line on the base substrate is located on a side of the orthographic projection of the data line on the base substrate facing an orthographic projection of the power line on the base substrate.

In some embodiments of the present disclosure, the display panel further includes a first transfer portion, the first transfer portion is located on a same conductive layer as the first bridging portion, an orthographic projection of the first transfer portion on the base substrate is located between orthographic projections of two first signal connection lines adjacent in the first direction on the base substrate, and the orthographic projection of the first transfer portion on the base substrate is located between orthographic projections of two adjacent first signal lines on the base substrate; and, the pixel driving circuit connected to the first electrode portion and the second electrode portion is correspondingly provided with the first transfer portion, the first transfer portion is connected to the pixel driving circuit corresponding to the first transfer portion, and the first transfer portion is connected to the power line in the pixel driving circuit connected to the second electrode portion corresponding to the first transfer portion.

In some embodiments of the present disclosure, the first bridging portion is further connected to the pixel driving circuit corresponding to the first bridging portion, the first bridging portion includes a first connection portion, an orthographic projection of the first connection portion on the base substrate extends in the second direction, and the first connection portion is connected to the pixel driving circuit; the first transfer portion includes a second connection portion, an orthographic projection of the second connection portion on the base substrate extends in the second direction, and the second connection portion is connected to the pixel driving circuit; the display panel further includes a data line, an orthographic projection of the data line on the base substrate extends in the second direction, and the data line is configured to provide a data signal to the pixel driving circuit; the orthographic projection of the first connection portion on the base substrate is located between orthographic projections of two adjacent data lines on the base substrate; and/or, the orthographic projection of the second connection portion on the base substrate is located between orthographic projections of two adjacent data lines on the base substrate.

In some embodiments of the present disclosure, an orthographic projection of the first signal connection line on the base substrate does not overlap with an orthographic projection of the electrode portion on the base substrate.

In some embodiments of the present disclosure, the first electrode portion includes a first side edge, and an extension direction of an orthographic projection of the first side edge on the base substrate intersects with the second direction; the first signal connection line includes a first line sub-segment and a second line sub-segment; an orthographic projection of the first line sub-segment on the base substrate is parallel to the orthographic projection of the first side edge on the base substrate; and, the second line sub-segment is connected to the first line sub-segment, and an extension direction of an orthographic projection of the second line sub-segment on the base substrate is parallel to the second direction.

In some embodiments of the present disclosure, the display panel further includes a pixel driving circuit, the pixel driving circuit includes a driving transistor and a fifth transistor, a first electrode of the fifth transistor is connected to a power line, and a second electrode of the fifth transistor is connected to a first electrode of the driving transistor. The display panel further includes a first active layer, the first active layer is located on a side of the base substrate, the first active layer includes a third active portion and a fifth active portion, the third active portion is configured to form a channel region of the driving transistor, and the fifth active portion is configured to form a channel region of the fifth transistor. An orthographic projection of the first signal connection line on the base substrate is located on a side of an orthographic projection of the third active portion on the base substrate close to an orthographic projection of the fifth active portion on the base substrate.

In some embodiments of the present disclosure, the display panel further includes a light-emitting unit, a pixel driving circuit, a power line and a second initial signal line, the pixel driving circuit is connected to a first electrode of the light-emitting unit, the power line is configured to provide a high-level power signal to the pixel driving circuit, the second initial signal line is configured to provide an initial signal line to a first electrode of the light-emitting unit, a first signal line is configured to form the second initial signal line, and/or a second signal line is configured to form the power line.

In some embodiments of the present disclosure, the first signal lines, the first signal connection lines, the first bridging portions are located in a same conductive layer; the first signal lines and the first signal connection lines are connected in a same layer; and, the plurality of second signal lines are located in a same conductive layer.

In some embodiments of the present disclosure, the display panel includes a pixel driving circuit and a light-emitting unit; and the pixel driving circuit includes a driving transistor, a first transistor, a second transistor, a fourth transistor, a fifth transistor, a sixth transistor, a seventh transistor, and a capacitor; a first electrode of the first transistor is connected to a first initial signal line, and a second electrode of the first transistor is connected to a gate of the driving transistor; a first electrode of the second transistor is connected to the gate of the driving transistor, and a second electrode of the second transistor is connected to a second electrode of the driving transistor; a first electrode of the fourth transistor is connected to a data line, and a second electrode of the fourth transistor is connected to a first electrode of the driving transistor; a first electrode of the fifth transistor is connected to a power line, and a second electrode of the fifth transistor is connected to the first electrode of the driving transistor; a first electrode of the sixth transistor is connected to the second electrode of the driving transistor, and a second electrode of the sixth transistor is connected to a first electrode of the light-emitting unit; a first electrode of the seventh transistor is connected to a second initial signal line, and a second electrode of the seventh transistor is connected to the first electrode of the light-emitting unit; and, a first electrode of the capacitor is connected to the gate of the driving transistor, and a second electrode of the capacitor is connected to the power line

In some embodiments of the present disclosure, the display panel further includes a first active layer, a first conductive layer, a second active layer, and a third conductive layer; the first active layer is located on a side of the base substrate; the first active layer includes a third active portion, a fourth active portion, a fifth active portion, a sixth active portion, and a seventh active portion; the third active portion is configured to form a channel region of the driving transistor, the fourth active portion is configured to form a channel region of the fourth transistor, the fifth active portion is configured to form a channel region of the fifth transistor, the sixth active portion is configured to form a channel region of the sixth transistor, and the seventh active portion is configured to form a channel region of the seventh transistor; the first conductive layer is located on a side of the first active layer away from the base substrate; the first conductive layer includes a first gate line, an enable signal line, a second reset signal line, and a first conductive portion; an orthographic projection of the first gate line on the base substrate extends in the first direction and covers an orthographic projection of the fourth active portion on the base substrate; an orthographic projection of the enable signal line on the base substrate extends in the first direction, and covers an orthographic projection of the fifth active portion on the base substrate and an orthographic projection of the sixth active portion on the base substrate; an orthographic projection of the second reset signal line on the base substrate extends in the first direction and covers an orthographic projection of the seventh active portion on the base substrate; an orthographic projection of the first conductive portion on the base substrate covers an orthographic projection of the third active portion on the base substrate; the second active layer is located on a side of the first conductive layer away from the base substrate; the second active layer includes a first active portion and a second active portion; the first active portion is configured to form a channel region of the first transistor, and the second active portion is configured to form a channel region of the second transistor; the third conductive layer is located on a side of the second active layer away from the base substrate; the third conductive layer includes a second gate line and a first reset signal line; an orthographic projection of the second gate line on the base substrate extends in the first direction and covers an orthographic projection of the second active portion on the base substrate; an orthographic projection of the first reset signal line on the base substrate extends in the first direction and covers an orthographic projection of the first active portion on the base substrate; where, the orthographic projection of the second reset signal line on the base substrate, the orthographic projection of the enable signal line on the base substrate, the orthographic projection of the first conductive portion on the base substrate, the orthographic projection of the second gate line on the base substrate, the orthographic projection of the first gate line on the base substrate, and the orthographic projection of the first reset signal line on the base substrate are distributed in the second direction in sequence.

In some embodiments of the present disclosure, the driving transistor, the fourth transistor, the fifth transistor, the sixth transistor, and the seventh transistor are P-type transistors; and, the first transistor and the second transistor are N-type transistors.

According to an aspect of the present disclosure, there is provided a display panel, and the display panel includes a base substrate, a plurality of first signal lines, a plurality of first signal connection lines, a plurality of second signal lines, and a plurality of first bridging portions; orthographic projections of the plurality of first signal lines on the base substrate extend in a first direction and are distributed at intervals in a second direction, and the first direction intersects with the second direction; an orthographic projection of a first signal connection line on the base substrate extends in the second direction, and the first signal connection line is connected between two first signal lines adjacent in the second direction to form a grid structure with the first signal lines; the second signal lines are located in a different conductive layer from the first signal lines, and orthographic projections of the plurality of second signal lines on the base substrate extend in the second direction and are distributed at intervals in the first direction; the first bridging portions are configured to be electrically connected to the second signal lines to form a grid structure with the second signal lines; where, an orthographic projection of a first bridging portion on the base substrate is located between orthographic projections of two first signal connection lines adjacent in the first direction on the base substrate, and the orthographic projection of the first bridging portion on the base substrate is located between orthographic projections of two adjacent first signal lines on the base substrate.

According to an aspect of the present disclosure, there is provided a display device, including the above display panel.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the description, illustrate embodiments consistent with the present disclosure and, together with the description, serve to explain the principles of the present disclosure. Obviously, the accompanying drawings in the following description are merely some embodiments of the present disclosure, and for those of ordinary skill in the art, other drawings may be obtained according to these drawings without creative efforts.

FIG. 1 is a structural layout of a display panel according to some embodiments of the present disclosure;

FIG. 2 is a structural layout of the fourth conductive layer in FIG. 1;

FIG. 3 is a structural layout of the fifth conductive layer in FIG. 1;

FIG. 4 is a structural layout of a display panel according to some embodiments of the present disclosure;

FIG. 5 is a structural layout of the fourth conductive layer in FIG. 4;

FIG. 6 is a structural layout of the fifth conductive layer in FIG. 4;

FIG. 7 is a structural layout of a display panel according to some embodiments of the present disclosure;

FIG. 8 is a structural layout of the fourth conductive layer in FIG. 7;

FIG. 9 is a structural layout of the fifth conductive layer in FIG. 7;

FIG. 10 is a schematic diagram of a circuit structure of a pixel driving circuit in a display panel according to the present disclosure;

FIG. 11 is a time sequence diagram of each node in a driving method for the pixel driving circuit in FIG. 10;

FIG. 12 is a structural layout of a display panel according to some embodiments of the present disclosure;

FIG. 13 is a structural layout of the shielding layer in FIG. 12;

FIG. 14 is a structural layout of the first active layer in FIG. 12;

FIG. 15 is a structural layout of the first conductive layer in FIG. 12;

FIG. 16 is a structural layout of the second conductive layer in FIG. 12;

FIG. 17 is a structural layout of the second active layer in FIG. 12;

FIG. 18 is a structural layout of the third conductive layer in FIG. 12;

FIG. 19 is a structural layout of the fourth conductive layer in FIG. 12;

FIG. 20 is a structural layout of the fifth conductive layer in FIG. 12;

FIG. 21 is a structural layout of the electrode layer and the pixel definition layer in FIG. 12;

FIG. 22 is a structural layout of the shielding layer and the first active layer in FIG. 12;

FIG. 23 is a structural layout of the shielding layer, the first active layer, and the first conductive layer in FIG. 12;

FIG. 24 is a structural layout of the shielding layer, the first active layer, the first conductive layer, and the second conductive layer in FIG. 12;

FIG. 25 is a structural layout of the shielding layer, the first active layer, the first conductive layer, the second conductive layer, and the second active layer in FIG. 12;

FIG. 26 is a structural layout of the shielding layer, the first active layer, the first conductive layer, the second conductive layer, the second active layer, and the third conductive layer in FIG. 12;

FIG. 27 is a structural layout of the shielding layer, the first active layer, the first conductive layer, the second conductive layer, the second active layer, the third conductive layer, and the fourth conductive layer in FIG. 12;

FIG. 28 is a structural layout of the shielding layer, the first active layer, the first conductive layer, the second conductive layer, the second active layer, the third conductive layer, the fourth conductive layer, the fifth conductive layer, and the pixel definition layer in FIG. 12;

FIG. 29 is a structural layout of a display panel according to some embodiments of the present disclosure;

FIG. 30 is a structural layout of the fourth conductive layer in FIG. 29;

FIG. 31 is a structural layout of the fifth conductive layer in FIG. 29;

FIG. 32 is a partial cross-sectional view of the display panel shown in FIG. 12 along a broken line AA.

### DETAILED DESCRIPTION

Example embodiments will now be described more fully with reference to the accompanying drawings. However, the example embodiments may be implemented in a variety of forms and should not be construed as limited to the examples set forth here. By contrast, these embodiments are provided so that the present disclosure will be more comprehensive and complete, and will fully convey the concepts of the example embodiments to those skilled in the art. The same reference numerals in the drawings denote the same or similar structures, and thus their detailed description will be omitted.

The terms “a”, “the” and “said” are configured to indicate the presence of one or more elements/components/or the like. The terms “including” and “having” are configured to indicate an open inclusion and mean that there may be additional elements/components/or the like in addition to the listed elements/components/or the like.

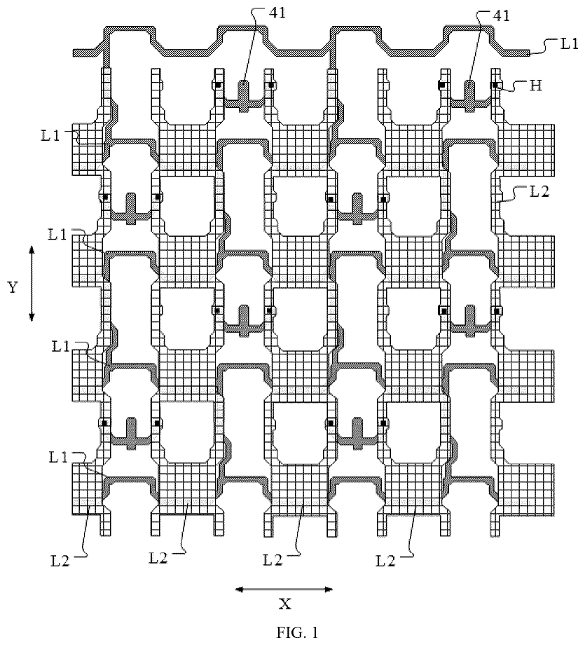

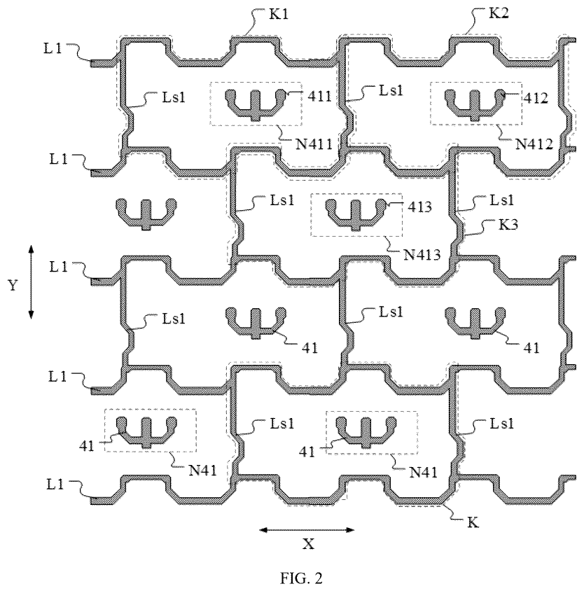

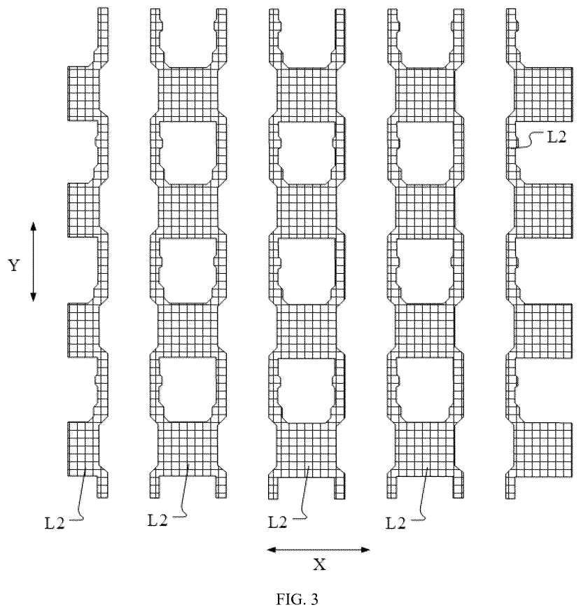

According to the example embodiments, there is first provided a display panel, which may include a base substrate, a fourth conductive layer, and a fifth conductive layer that are sequentially stacked. As shown in FIG. 1 to FIG. 3, FIG. 1 is a structural layout of a display panel according to some embodiments of the present disclosure, FIG. 2 is a structural layout of the fourth conductive layer in FIG. 1, and FIG. 3 is a structural layout of the fifth conductive layer in FIG. 1.

In some embodiments, the fourth conductive layer may include a plurality of first signal lines L1, a plurality of first signal connection lines Ls1, and a plurality of first bridging portions 41. Orthographic projections of the plurality of first signal lines L1 on the base substrate extends in a first direction X and are distributed at intervals in a second direction Y. The first direction X intersects with the second direction Y. For example, the first direction X may be a row direction, and the second direction Y may be a column direction. An orthographic projection of a first signal connection line Ls1 on the base substrate extends in the second direction Y, and a first signal connection line Ls1 is connected between two first signal lines L1 adjacent in the second direction Y to form a grid structure with the first signal lines L1. The fifth conductive layer may include a plurality of second signal lines L2. The second signal lines L2 and the first signal lines L1 are located in different conductive layers. Orthographic projections of the plurality of second signal lines L2 on the base substrate extend in the second direction Y and are distributed at intervals in the first direction X. A first bridging portion 41 is connected between two second signal lines L2 adjacent in the first direction X to form a grid structure with the second signal lines L2, where a second signal line L2 is connected to the first bridging portion 41 by using a through hole H. An orthographic projection of the first bridging portion 41 on the base substrate is located between orthographic projections of two first signal connection lines Ls1 adjacent in the first direction X on the base substrate, and the orthographic projection of the first bridging portion 41 on the base substrate is located between orthographic projections of two adjacent first signal lines L1 on the base substrate.

In some embodiments, the first signal lines L1 and the second signal lines L2 may provide different signals. Both the first signal lines L1 and the second signal lines L2 may form a grid structure. The first signal lines L1 of the grid structure and the second signal lines L2 of the grid structure have relatively smaller resistances, so that there is a relatively smaller voltage drop between the first signal lines L1 at different positions of the display panel, and there is a relatively smaller voltage drop between the second signal lines L2 at different positions of the display panel. According to such a setting, the display uniformity of the display panel may be improved, and the power consumption of the display panel may be reduced.

As shown in FIG. 1 to FIG. 3, the first signal lines L1, the first signal connection lines Ls1, and the first bridging portions 41 are located on the same conductive layer. It should be understood that in other example embodiments, the first signal lines L1, the first signal connection lines Ls1, and the first bridging portions 41 may also be located in any other conductive layer. For example, the first signal lines L1, the first signal connection lines Ls1, and the first bridging portions 41 may be located in different conductive layers. For another example, the first signal connection lines Ls1 and the first bridging portions 41 may be located in a same conductive layer, and the first signal connection lines Ls1 and the first signal lines L1 are located in different conductive layers.

In some embodiments, as shown in FIG. 1 to FIG. 3, two adjacent first signal connection lines Ls1 and two adjacent first signal lines L1 connected to the two adjacent first signal connection lines Ls1 form an annular structure K, and a plurality of annular structures K include a first annular structure K1, a second annular structure K2, and a third annular structure K3. The first annular structure K1 and the second annular structure K2 are distributed in the first direction X; the first annular structure K1 and the third annular structure K3 are distributed in the second direction Y, and the first annular structure K1 and the third annular structure K3 are provided in a staggered manner in the first direction X; the second annular structure K2 and the third annular structure K3 are distributed in the second direction Y, and the second annular structure K2 and the third annular structure K3 are provided in a staggered manner in the first direction X. The first bridging portions 41 whose orthographic projections on the base substrate being located in a same annular structure K form a bridging portion group N41. A plurality of bridging portion groups N41 include a first bridging portion group N411, a second bridging portion group N412, and a third bridging portion group N413. An orthographic projection of a first bridging portion group N411 on the base substrate is located within an orthographic projection of a first annular structure K1 on the base substrate, an orthographic projection of a second bridging portion group N412 on the base substrate is located within an orthographic projection of a second annular structure K2 on the base substrate, and an orthographic projection of a third bridging portion group N413 on the base substrate is located within an orthographic projection of a third annular structure K3 on the base substrate. The first bridging portion group N411 and the second bridging portion group N412 are respectively connected to different second signal lines L2, the first bridging portion group N411 and the third bridging portion group N413 are connected to at least one same second signal line L2, and the second bridging portion group N412 and the third bridging portion group N413 are connected to at least one same second signal line L2.

In some embodiments, there is no first bridging portion provided between the second signal line L2 connected to the first bridging portion group N411 and the second signal line L2 connected to the second bridging portion group N412, and a first signal connection line Ls1 may be provided at the position where there is no first bridging portion provided. Meanwhile, In some embodiments, the third bridging portion group N413 is connected to the second signal line L2 correspondingly connected to the first bridging portion group N411 and the second bridging portion group N412, so that each second signal line L2 may be connected to each other through the bridging portion groups N41.

As shown in FIG. 1 to FIG. 3, In some embodiments, the plurality of second signal lines L2 connected to any bridging portion group N41 may be divided into two parts, and the two parts of the second signal lines L2 may be respectively connected to two bridging portion group N41 distributed in the second direction relative to the bridging portion group N41.

As shown in FIG. 1 to FIG. 3, In some embodiments, a first annular structure K1 and a second annular structure K2 may share a same first signal connection line Ls1; a first annular structure K1 and a third annular structure K3 may share a partial structure of a same first signal line L1; and, a second annular structure K2 and a third annular structure K3 may share a partial structure of a same first signal line L1.

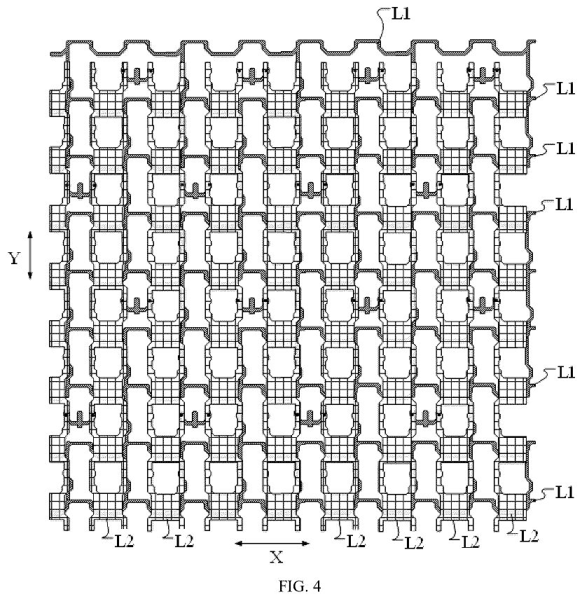

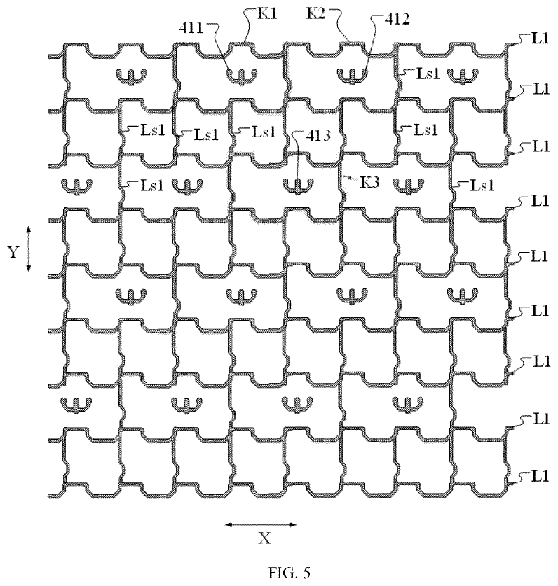

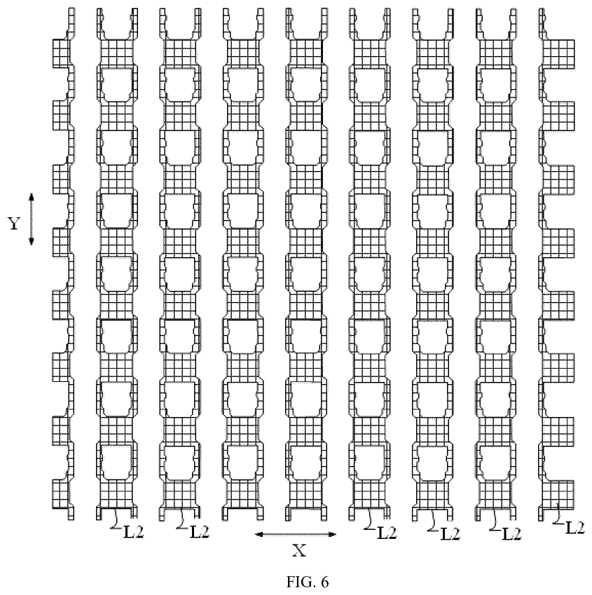

It should be understood that, in other example embodiments, the first annular structure K1 and the second annular structure K2 may also be provided at intervals in the first direction X; the first annular structure K1 and the third annular structure K3 may also be provided at intervals in the second direction Y; and, the second annular structure K2 and the third annular structure K3 may also be provided at intervals in the second direction Y. As shown in FIG. 4 to FIG. 6, FIG. 4 is a structural layout of a display panel according to some embodiments of the present disclosure, FIG. 5 is a structural layout of the fourth conductive layer in FIG. 4, and FIG. 6 is a structural layout of the fifth conductive layer in FIG. 4. In these figures, the first annular structure K1 and the third annular structure K3 may also be provided at intervals in the second direction Y; and, the second annular structure K2 and the third annular structure K3 may also be provided at intervals in the second direction Y.

As shown in FIG. 1 to FIG. 3, a bridging portion group N41 includes a first bridging portion 41. The first signal connection line Ls1 connected between adjacent first signal lines L1 in a same group forms a first signal connection line row, and the first bridging portion 41 located between adjacent first signal lines L1 in a same group forms a first bridging portion row. Among the first signal connection line rows adjacent in the second direction Y, orthographic projections of the first signal connection lines Ls1 located in different first signal connection line rows on the base substrate are sequentially and alternately distributed in the first direction. Among the first bridging portion rows adjacent in the second direction Y, orthographic projections of the first bridging portions 41 located in different first bridging portion rows on the base substrate are sequentially and alternately distributed in the first direction X.

In some embodiments, orthographic projections of the first signal connection lines Ls1 located in the same first signal connection line row on the base substrate are distributed at equal intervals or approximately equal intervals in the first direction. Orthographic projections of the first bridging portions 41 located in the same first bridging portion row on the base substrate are distributed at equal intervals or approximately equal intervals in the first direction. In some embodiments, structures A being distributed at approximately equal intervals in a direction may be appreciated as that, the maximum value of the distance between structures A adjacent in the first direction is L1, the minimum value of the distance between structures A adjacent in the first direction is L2, and (L1−L2)/L1 is less than or equal to 0.2. For example, (L1−L2)/L1 may be equal to 0.2, 0.1, 0.05, etc.

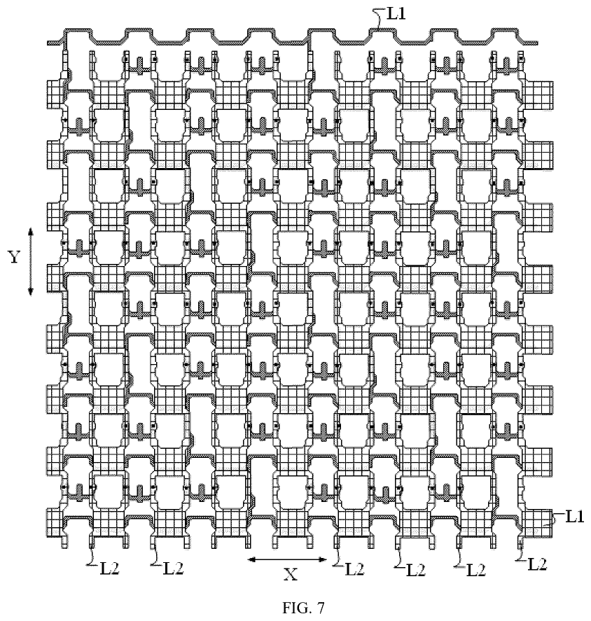

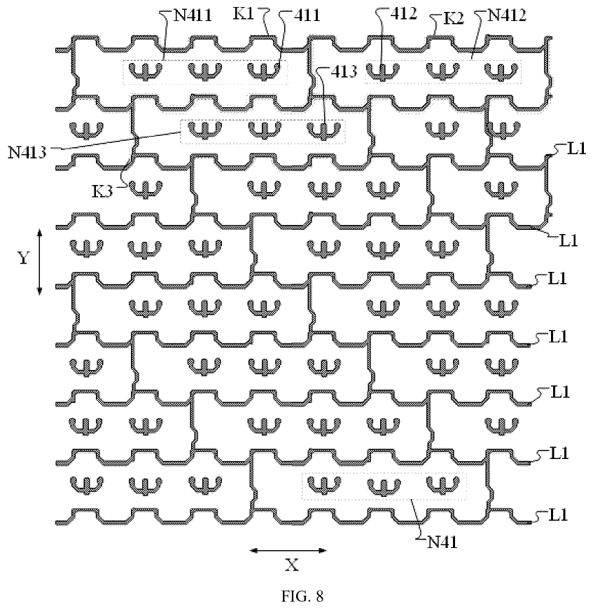

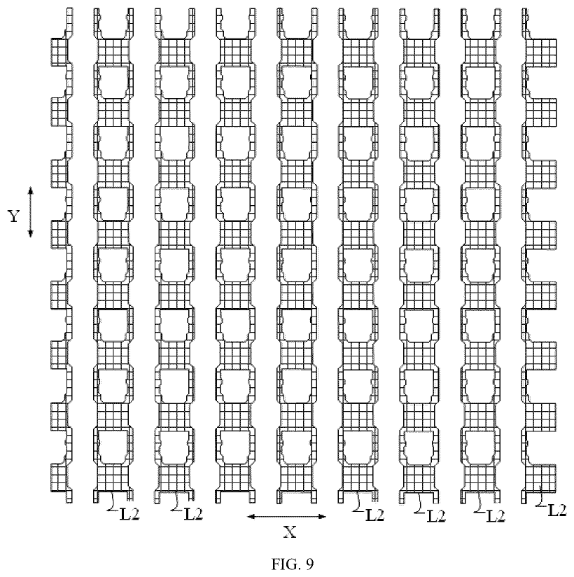

It should be understood that, in other example embodiments, a bridging portion group N41 may include a plurality of first bridging portions 41. As shown in FIG. 7 to FIG. 9, FIG. 7 is a structural layout of a display panel according to some embodiments of the present disclosure, FIG. 8 is a structural layout of the fourth conductive layer in FIG. 7, and FIG. 9 is a structural layout of the fifth conductive layer in FIG. 7. In these figures, a bridging portion group N41 may include a plurality of first bridging portions 41.

As shown in FIG. 1 to FIG. 3, the first bridging portions 41 located between two adjacent first signal lines L1 in a same group are distributed at intervals in the first direction X. The distance in the first direction X between orthographic projections of two first signal connection lines Ls1 in each annular structure K on the base substrate may be the same or approximately the same, and each bridging portion group N41 may include a same quantity of first bridging portions. It should be noted that, the distance in the first direction X between the orthographic projections of two first signal connection lines Ls1 in each annular structure K on the base substrate being approximately the same may be appreciated as that, the maximum value of the distance in the first direction X between the orthographic projections of two first signal connection lines Ls1 in each annular structure K on the base substrate is S1, the minimum value of the distance in the first direction X between the orthographic projections of two first signal connection lines Ls1 in each annular structure K on the base substrate is S2, and (S1−S2)/S1 is less than or equal to 0.2. For example, (S1−S2)/S1 may be equal to 0.2, 0.1, 0.05, etc.

It should be understood that, in other example embodiments, different quantities of first bridging portions may also be included in the different bridging portion groups N41.

As shown in FIG. 1 to FIG. 9, the first bridging portion in the first bridging portion group N411 includes a first bridging sub-portion 411, the first bridging portion in the second bridging portion group N412 includes a second bridging sub-portion 412, and the first bridging portion in the third bridging portion group N413 includes a third bridging sub-portion 413. In the first direction, an orthographic projection of the third bridging sub-portion 413 on the base substrate is located between an orthographic projection of the first bridging sub-portion 411 on the base substrate and an orthographic projection of the second bridging sub-portion 412 on the base substrate. The orthographic projection of the first bridging sub-portion 411 on the base substrate and the orthographic projection of the second bridging sub-portion 412 on the base substrate are provided adjacent in the first direction X. That is, there is no other first bridging portion provided between the first bridging sub-portion 411 and the second bridging sub-portion 412. The spare space between the first bridging sub-portion 411 and the second bridging sub-portion 412 may be configured to provide the first signal connection line Ls1, and the orthographic projection of the first signal connection line Ls1 on the base substrate is located between the orthographic projection of the first bridging sub-portion 411 on the base substrate and the orthographic projection of the second bridging sub-portion 412 on the base substrate.

In some embodiments, the first signal line and the second signal line may respectively provide any signal to the display panel. For example, the first signal line and the second signal line may be configured to provide a high-level power signal, a low-level power signal, an initial signal, or the like.

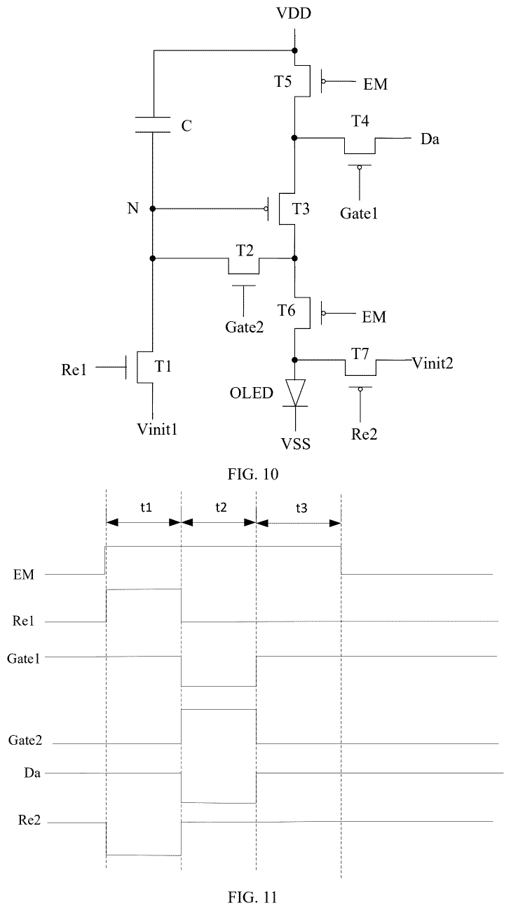

As shown in FIG. 10, it is a schematic diagram of a circuit structure of a pixel driving circuit in the display panel of the present disclosure. The pixel driving circuit may include: a driving transistor T3, a first transistor T1, a second transistor T2, a fourth transistor T4, a fifth transistor T5, a sixth transistor T6, a seventh transistor T7, and a capacitor C. In some embodiments, the first electrode of the fourth transistor T4 is connected to the data signal end Da, the second electrode of the fourth transistor T4 is connected to the first electrode of the driving transistor T3, and the gate of the fourth transistor T4 is connected to the first gate driving signal end Gate1. The first electrode of the fifth transistor T5 is connected to the first power end VDD, the second electrode of the fifth transistor T5 is connected to the first electrode of the driving transistor T3, and the gate of the fifth transistor T5 is connected to the enable signal end EM. The gate of the driving transistor T3 is connected to the node N. The first electrode of the second transistor T2 is connected to the node N, the second electrode of the second transistor T2 is connected to the second electrode of the driving transistor T3, and the gate of the second transistor T2 is connected to the second gate driving signal end Gate2. The first electrode of the sixth transistor T6 is connected to the second electrode of the driving transistor T3, the second electrode of the sixth transistor T6 is connected to the second electrode of the seventh transistor T7, and the gate of the sixth transistor T6 is connected to the enable signal end EM. The first electrode of the seventh transistor T7 is connected to the second initial signal end Vinit2, and the gate of the seventh transistor T7 is connected to the second reset signal end Re2. The second electrode of the first transistor T1 is connected to the node N, the first electrode of the first transistor T1 is connected to the first initial signal end Vinit1, and the gate of the first transistor T1 is connected to the first reset signal end Re1. The first electrode of the capacitor C is connected to the node N, and the second electrode of the capacitor C is connected to the first power end VDD. The pixel driving circuit may be connected to a light-emitting unit OLED, and the pixel driving circuit is configured to drive the light-emitting unit OLED to emit light. The first electrode of the light-emitting unit OLED may be connected to the second electrode of the sixth transistor T6, and the second electrode of the light-emitting unit may be connected to the second power end VSS. The first electrode of the light-emitting unit may be the anode of the light-emitting unit, and the second electrode of the light-emitting unit may be the cathode of the light-emitting unit. In some embodiments, the first transistor T1 and the second transistor T2 may be N-type transistors. For example, the first transistor T1 and the second transistor T2 may be N-type metal oxide transistors. The N-type transistor has a relatively smaller leakage current, so that leakage of electricity in the node N through the first transistor T1 and the second transistor T2 during the light-emitting stage may be avoided. Meanwhile, the driving transistor T3, the fourth transistor T4, the fifth transistor T5, the sixth transistor T6, and the seventh transistor T7 may be P-type transistors. For example, the driving transistor T3, the fourth transistor T4, the fifth transistor T5, the sixth transistor T6, and the seventh transistor T7 may be P-type low-temperature polycrystalline silicon transistors. The P-type transistor has a relatively higher carrier mobility, which is conducive to achieving a display panel with a high-resolution, a high response speed, a high pixel density, and a high aperture ratio. The first initial signal end and the second initial signal end may output the same voltage signal or different voltage signals according to the actual situations.

As shown in FIG. 11, FIG. 11 is a time sequence diagram of each node in the driving method for the pixel driving circuit in FIG. 10. In some embodiments, Gate1 represents the time sequence of the first gate driving signal end Gate1, Gate2 represents the time sequence of the second gate driving signal end Gate2, Re1 represents the time sequence of the first reset signal end Re1, Re2 represents the time sequence of the second reset signal end Re2, EM represents the time sequence of the enabling signal end EM, and Da represents the time sequence of the data signal end Da. The driving method for the pixel driving circuit may include a reset stage T1, a data writing stage T2, and a light-emitting stage T3. In the reset stage T1, the first reset signal end Re1 outputs a high-level signal, the second reset signal end Re2 outputs a low-level signal, the first transistor T1 and the seventh transistor T7 are turned on, the first initial signal end Vinit1 inputs a first initial signal to the node N, and the second initial signal end Vinit2 inputs a second initial signal to the first electrode of the light-emitting unit OLED. In the data writing stage T2, the second gate driving signal end Gate2 outputs a high-level signal, the first gate driving signal end Gate1 outputs a low-level signal, the fourth transistor T4 and the second transistor T2 are turned on, and the data signal end Da outputs a data signal to write the compensation voltage Vdata+Vth to the node N, where Vdata is the voltage of the data signal, and Vth is the threshold voltage of the driving transistor T3. In the light-emitting stage T3, the enable signal end EM outputs a low-level signal, the sixth transistor T6 and the fifth transistor T5 are turned on, and the driving transistor T3 drives the light-emitting unit to emit light under the action of the compensation voltage Vdata+Vth stored in the capacitor C. In the pixel driving circuit of the present disclosure, for the output current of the driving transistor, I=(μWCox/2L)(Vdata+Vth−Vdd−Vth)2, where I is the output current of the driving transistor, μ is the carrier mobility, Cox is the gate capacitance per unit area, W is the width of the channel of the driving transistor, L is the length of the channel of the driving transistor channel, Vgs is the gate source voltage difference of driving transistor, and Vth is the threshold voltage of the driving transistor. In the pixel driving circuit, the influence of the threshold of the driving transistor on the output current of the driving transistor may be avoided. It should be understood that, in other example embodiments, there may further be other driving methods for the pixel driving. For example, the seventh transistor T7 may be configured to reset the first electrode of the light-emitting unit in a time period between the data writing stage T2 and the light-emitting stage T3.

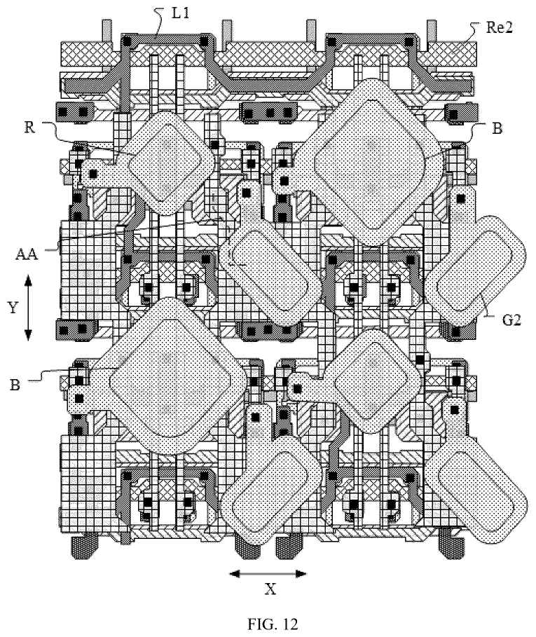

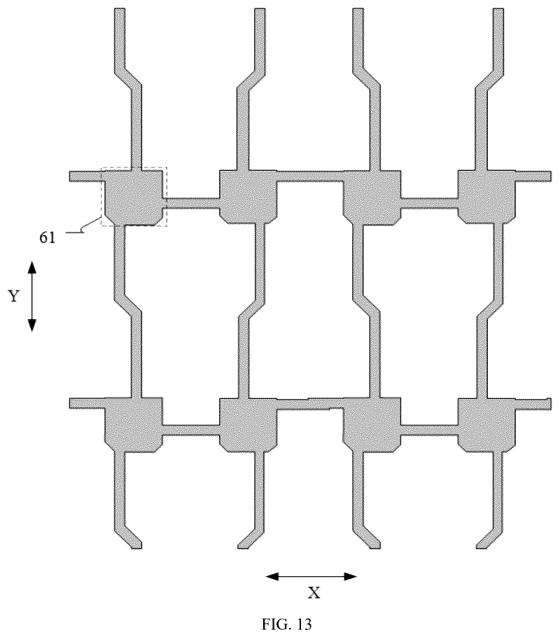

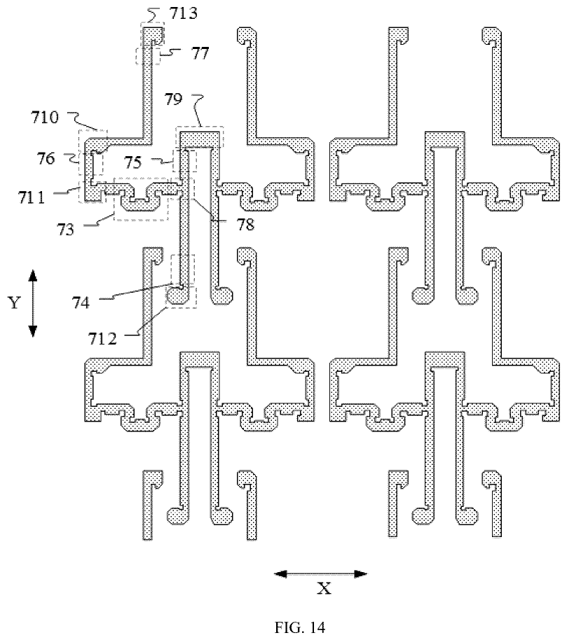

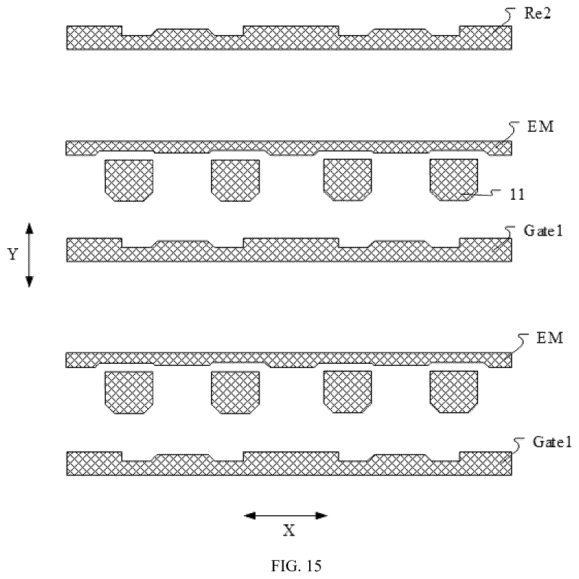

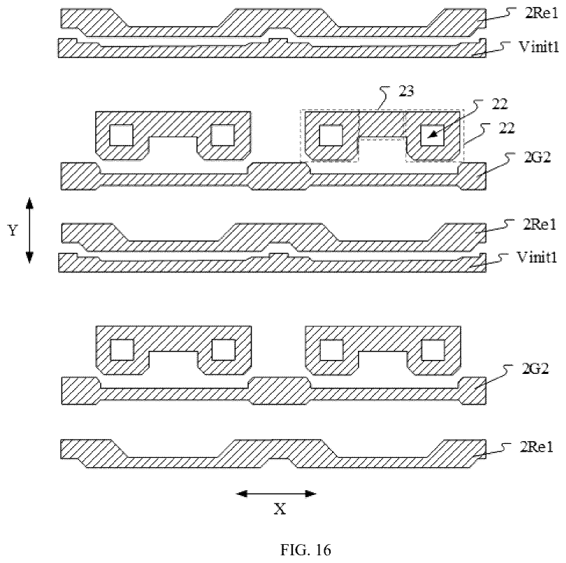

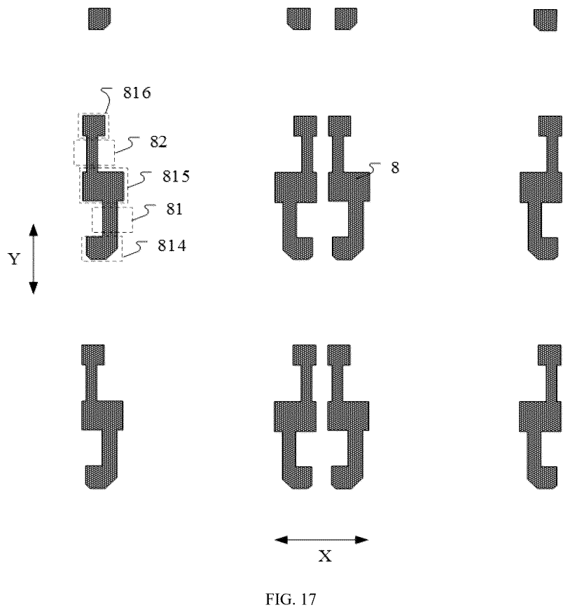

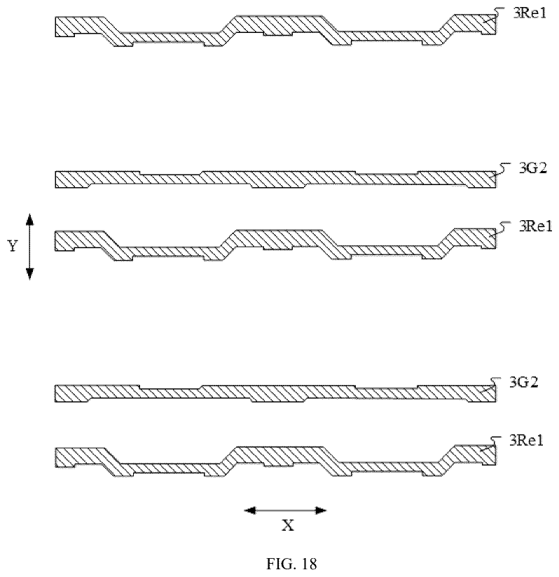

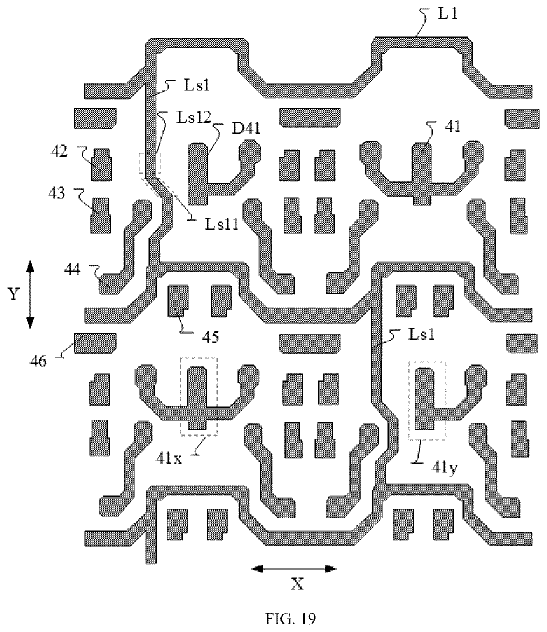

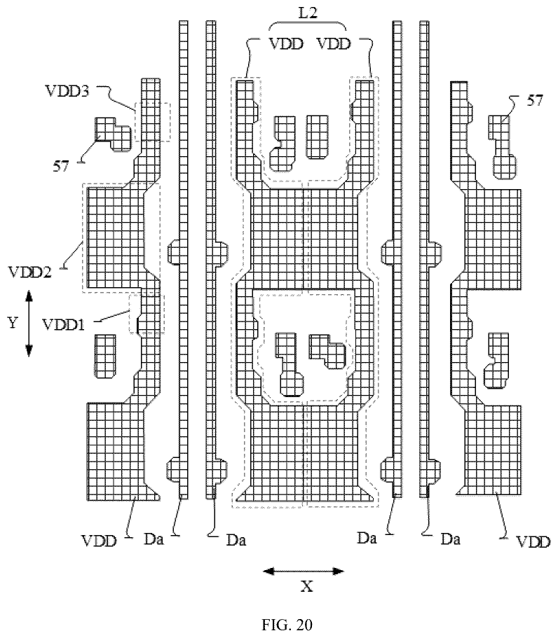

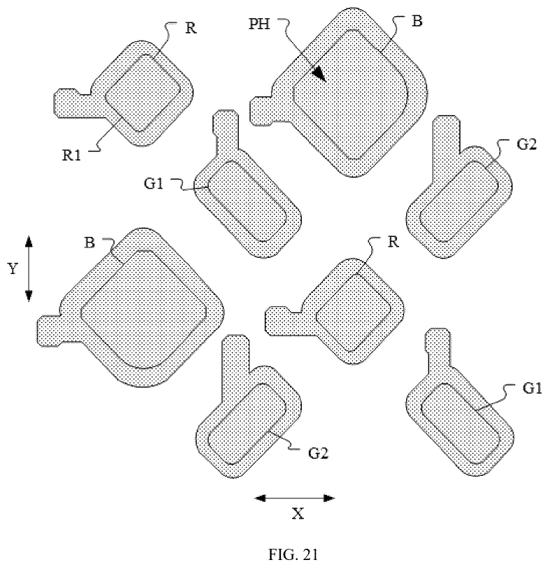

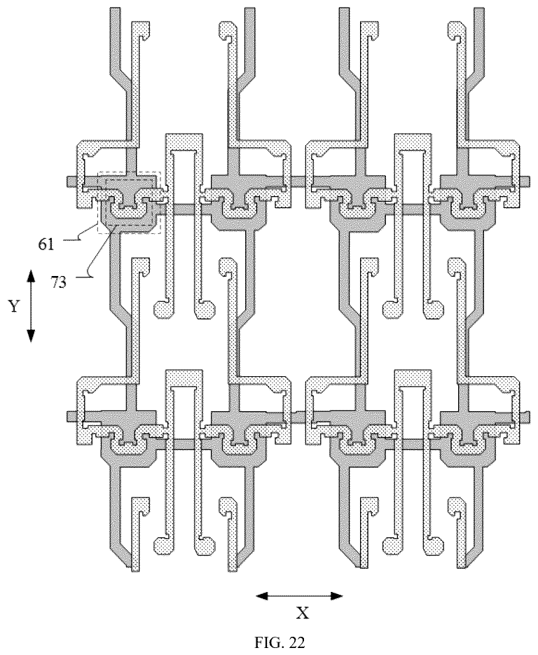

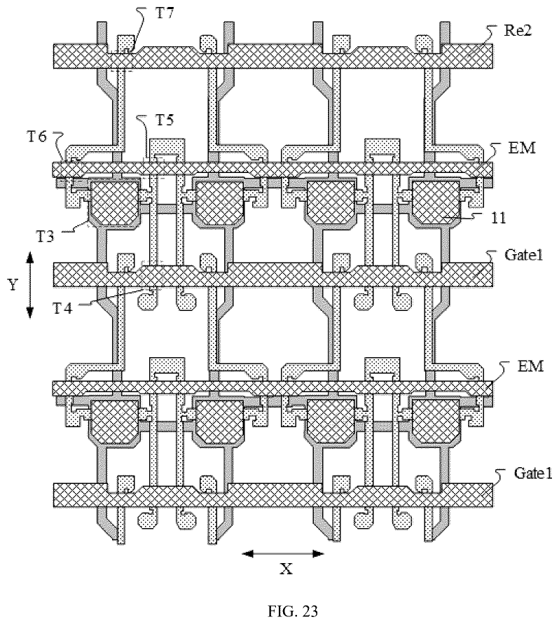

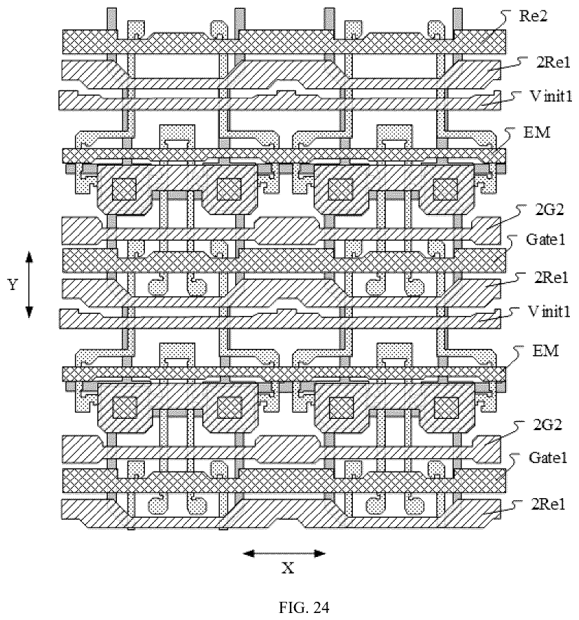

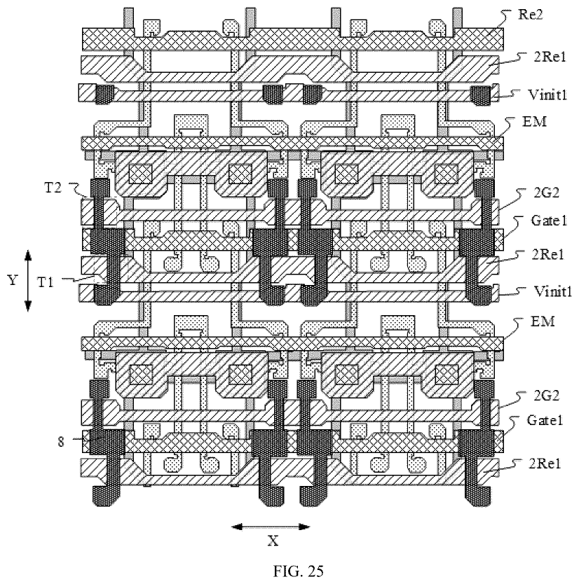

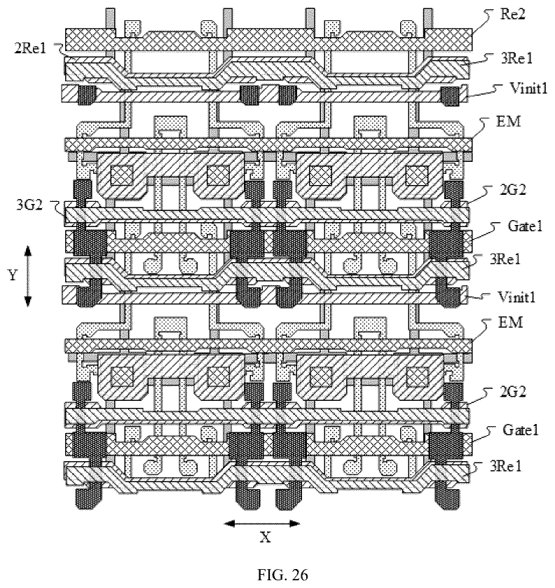

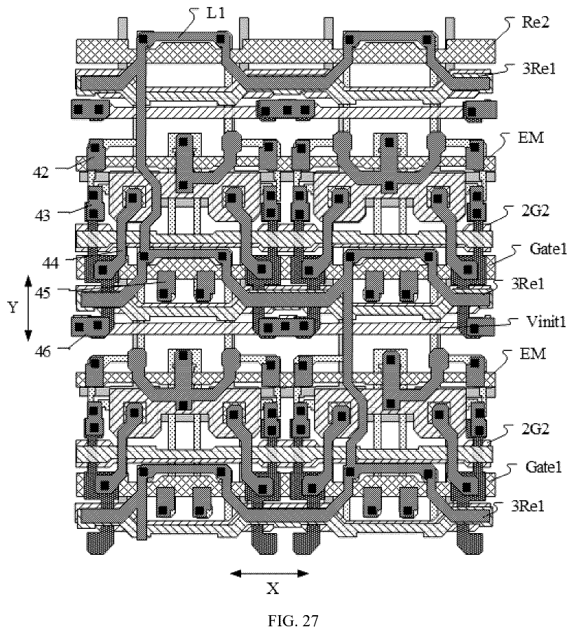

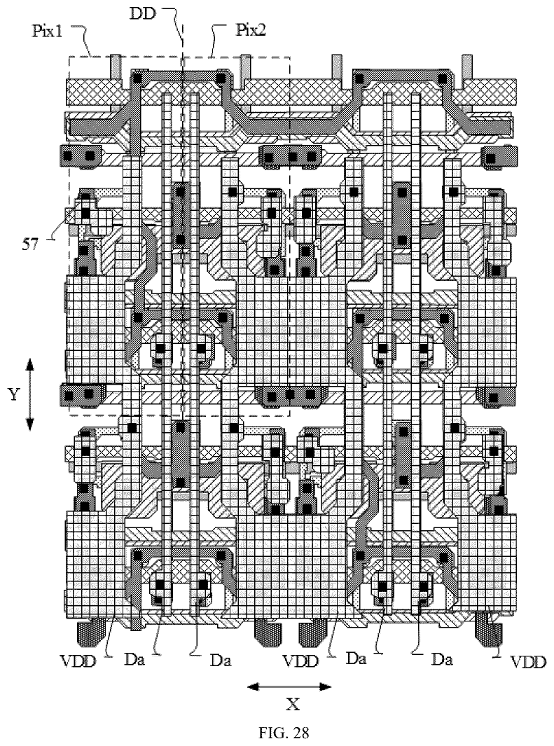

In some embodiments, the display panel may include a base substrate, a shielding layer, a first active layer, a first conductive layer, a second conductive layer, a second active layer, a third conductive layer, a fourth conductive layer, a fifth conductive layer, an electrode layer, and a pixel definition layer that are sequentially stacked, where an insulating layer may be provided between the adjacent layers. As shown in FIG. 12 to FIG. 28, FIG. 12 is a structural layout of a display panel according to some embodiments of the present disclosure, FIG. 13 is a structural layout of the shielding layer in FIG. 12, FIG. 14 is a structural layout of the first active layer in FIG. 12, FIG. 15 is a structural layout of the first conductive layer in FIG. 12, FIG. 16 is a structural layout of the second conductive layer in FIG. 12, FIG. 17 is a structural layout of the second active layer in FIG. 12, FIG. 18 is a structural layout of the third conductive layer in FIG. 12, FIG. 19 is a structural layout of the fourth conductive layer in FIG. 12, FIG. 20 is a structural layout of the fifth conductive layer in FIG. 12, FIG. 21 is a structural layout of the electrode layer and the pixel definition layer in FIG. 12, FIG. 22 is a structural layout of the shielding layer and the first active layer in FIG. 12, FIG. 23 is a structural layout of the shielding layer, the first active layer, and the first conductive layer in FIG. 12, FIG. 24 is a structural layout of the shielding layer, the first active layer, the first conductive layer, and the second conductive layer in FIG. 12, FIG. 25 is a structural layout of the shielding layer, the first active layer, the first conductive layer, the second conductive layer, and the second active layer in FIG. 12, FIG. 26 is a structural layout of the shielding layer, the first active layer, the first conductive layer, the second conductive layer, the second active layer, and the third conductive layer in FIG. 12, FIG. 27 is a structural layout of the shielding layer, the first active layer, the first conductive layer, the second conductive layer, the second active layer, the third conductive layer, and the fourth conductive layer in FIG. 12, and FIG. 28 is a structural layout of the shielding layer, the first active layer, the first conductive layer, the second conductive layer, the second active layer, the third conductive layer, the fourth conductive layer, the fifth conductive layer, and the pixel definition layer in FIG. 12. The display panel may include a plurality of pixel driving circuits shown in FIG. 10. As shown in FIG. 28, the plurality of pixel driving circuits may include a first pixel driving circuit Pix1 and a second pixel driving circuit Pix2 distributed adjacent in the first direction X; and, at least partial structure of the first pixel driving circuit Pix1 and at least partial structure of the second pixel driving circuit Pix2 may be symmetrically provided in a mirror manner relative to a mirror symmetry plane DD. In some embodiments, the mirror symmetry plane DD may be perpendicular to the base substrate. The orthographic projection of the first pixel driving circuit Pix1 on the base substrate and the orthographic projection of the second pixel driving circuit Pix2 on the base substrate may be symmetrically provided in an axial symmetry manner relative to the intersection line between the mirror symmetry plane DD and the base substrate. The first pixel driving circuit Pix1 and the second pixel driving circuit Pix2 may form a repeating unit, and the display panel may include a plurality of repeating units distributed in an array in the first direction X and the second direction Y.

As shown in FIG. 12, FIG. 13, and FIG. 22, the shielding layer may include a plurality of shielding portions 61, and adjacent shielding portions 61 may be connected to each other. It should be understood that, in other example embodiments, the display panel may not include a shielding layer.

As shown in FIG. 12, FIG. 14, and FIG. 22, the first active layer may include a third active portion 73, a fourth active portion 74, a fifth active portion 75, a sixth active portion 76, and a seventh active portion 77, where the third active portion 73 may be configured to form the channel region of the driving transistor T3, the fourth active portion 74 may be configured to form the channel region of the fourth transistor T4, the fifth active portion 75 may be configured to form the channel region of the fifth transistor T5, the sixth active portion 76 may be configured to form the channel region of the sixth transistor T6, and the seventh active portion 77 may be configured to form the channel region of the seventh transistor T7. The first active layer further includes an eighth active portion 78, a ninth active portion 79, a tenth active portion 710, an eleventh active portion 711, a twelfth active portion 712, and a thirteenth active portion 713, where the ninth active portion 79 is connected to a side of the fifth active portion 75 away from the third active portion 73, and the ninth active portion 79 is connected between two fifth active portions 75 adjacent in the first direction X. The tenth active portion 710 is connected between the sixth active portion 76 and the seventh active portion 77, the eleventh active portion 711 is connected between the sixth active portion 76 and the third active portion 73, the twelfth active portion 712 is connected to an end of the fourth active portion 74 away from the third active portion 73, and the thirteenth active portion 713 is connected to an end of the seventh active portion 77 away from the sixth active portion 76. In some embodiments, an orthographic projection of the shielding portion 61 on the base substrate may cover an orthographic projection of the third active portion 73 on the base substrate, and the shielding portion 61 may reduce the influence of light on driving characteristics of the driving transistor T3. The first active layer may be formed of a polysilicon material; and correspondingly, the driving transistor T3, the fourth transistor T4, the fifth transistor T5, the sixth transistor T6, and the seventh transistor T7 may be P-type low-temperature polysilicon thin film transistors.

As shown in FIG. 12, FIG. 15, and FIG. 23, the first conductive layer may include a first conductive portion 11, a first gate line Gate1, an enable signal line EM, and a second reset signal line Re2. The first gate line Gate1 may be configured to provide the first gate driving signal end in FIG. 10; the enable signal line EM may be configured to provide the enable signal end in FIG. 10; and the second reset signal line Re2 may be configured to provide the second reset signal end in FIG. 10. The orthographic projection of the first gate line Gate1 on the base substrate, the orthographic projection of the enable signal line EM on the base substrate, and the orthographic projection of the second reset signal line Re2 on the base substrate may all extend in the first direction X. The orthographic projection of the first gate line Gate1 on the base substrate covers the orthographic projection of the fourth active portion 74 on the base substrate, and a partial structure of the first gate line Gate1 is configured to form the gate of the fourth transistor. The orthographic projection of the enable signal line EM on the base substrate covers the orthographic projection of the fifth active portion 75 on the base substrate and the orthographic projection of the sixth active portion 76 on the base substrate, and a partial structure of the enable signal line EM may be respectively configured to form the gate of the fifth transistor T5 and the gate of the sixth transistor T6. The orthographic projection of the second reset signal line Re2 on the base substrate may cover the orthographic projection of the seventh active portion 77 on the base substrate, and a partial structure of the second reset signal line Re2 may be configured to form the gate of the seventh transistor T7. The orthographic projection of the first conductive portion 11 on the base substrate covers the orthographic projection of the third active portion 73 on the base substrate, and the first conductive portion 11 may be configured to form the gate of the driving transistor T3 and the first electrode of the capacitor C. As shown in FIG. 23, the first gate line Gate1 in the present row of pixel driving circuits may be reused as the second reset signal line Re2 in a next row of pixel driving circuits; and the display panel may be driven row by row from top to bottom, or may be driven row by row from bottom to top. According to such arrangement, the integration level of the pixel driving circuit may be improved, and the layout area of the pixel driving circuit may be reduced. The shielding layer may be connected to a stable power end. For example, the shielding layer may be connected to the first power end, the first initial signal end, the second initial signal end in FIG. 10, or the like. The noise influence of other signals on the driving transistor T3 may be shielded by the shielding portion 61. In the display panel, the first conductive layer may be used as a mask to perform a conductive treatment on the first active layer. That is, the region covered by the first conductive layer in the first active layer may form the channel region of the transistor, and the region not covered by the first conductive layer in the first active layer may form a conductor structure.

As shown in FIG. 12, FIG. 16, and FIG. 24, the second conductive layer may include a first initial signal line Vinit1, a third reset signal line 2Re1, a third gate line 2G2, and a plurality of second conductive portions 22, where the first initial signal line Vinit1 is configured to provide the first initial signal end in FIG. 10, the third reset signal line 2Re1 may be configured to provide the first reset signal end in FIG. 10, and the third gate line 2G2 may be configured to provide the second gate driving signal end in FIG. 10. The orthographic projection of the first initial signal line Vinit1 on the base substrate, the orthographic projection of the third reset signal line 2Re1 on the base substrate, and the orthographic projection of the third gate line 2G2 on the base substrate may all extend in the first direction X. As shown in FIG. 16, the second conductive layer may further include a plurality of third connection portions 23, and a third connection portions 23 is connected between two adjacent second conductive portions 22 in the same repeating unit.

As shown in FIG. 12, FIG. 17 and FIG. 25, the second active layer may include an active portion 8. The active portion 8 may include a first active portion 81, a second active portion 82, a fourteenth active portion 814, a fifteenth active portion 815, and a sixteenth active portion 816. The first active portion 81 is configured to form the channel region of the first transistor T1, and the second active portion 82 is configured to form the channel region of the second transistor T2. The fifteenth active portion 815 is connected between the first active portion 81 and the second active portion 82. The fourteenth active portion 814 is connected to an end of the first active portion 81 away from the second active portion 82, and the sixteenth active portion 816 is connected to an end of the second active portion 82 away from the first active portion 81. In some embodiments, the second active layer may be formed of indium gallium zinc oxide; and correspondingly, the first transistor T1 and the second transistor T2 may be N-type metal oxide thin film transistors. The orthographic projection of the third gate line 2G2 on the base substrate may cover the orthographic projection of the second active portion 82 on the base substrate, and a partial structure of the third gate line 2G2 may be configured to form the bottom gate of the second transistor T2. The orthographic projection of the third reset signal line 2Re1 on the base substrate may cover the orthographic projection of the first active portion 81 on the base substrate, and a partial structure of the third reset signal line 2Re1 may be configured to form the bottom gate of the first transistor T1.

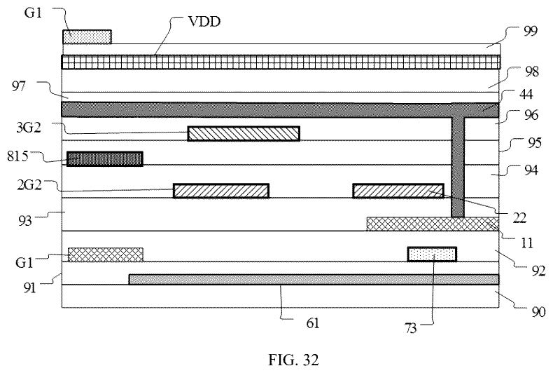

As shown in FIG. 12, FIG. 18, and FIG. 26, the third conductive layer may include a first reset signal line 3Re1 and second gate line 3G2. The orthographic projection of the first reset signal line 3Re1 on the base substrate and the orthographic projection of the second gate line 3G2 on the base substrate may all extend in the first direction X. The first reset signal line 3Re1 may be configured to provide the first reset signal end in FIG. 10, the orthographic projection of the first reset signal line 3Re1 on the base substrate may cover the orthographic projection of the first active portion 81 on the base substrate, a partial structure of the first reset signal line 3Re1 may be configured to form the top gate of the first transistor T1, and the first reset signal line 3Re1 may be connected to the third reset signal line 2Re1 through the via hole located in the frame region of the display panel. The second gate line 3G2 may be configured to provide the second gate driving signal end in FIG. 32. The orthographic projection of the second gate line 3G2 on the base substrate may cover the orthographic projection of the second active portion 82 on the base substrate, a partial structure of the second gate line 3G2 may be configured to form the top gate of the second transistor T2, and the second gate line 3G2 may be connected to the third gate line 2G2 through the via hole located in the frame region of the display panel. Furthermore, in the display panel, the third conductive layer may be used as a mask to perform a conductive treatment on the second active layer; that is, the region covered by the third conductive layer in the second active layer may form the channel region of the transistor, and the region not covered by the third conductive layer in the second active layer forms a conductor structure.

As shown in FIG. 12, FIG. 19, and FIG. 27, the fourth conductive layer may include the first signal line L1, the first signal connection line Ls1, and the first bridging portion 41 mentioned above. The first signal line L1 may be configured to provide the second initial signal end in FIG. 10. The fourth conductive layer may further include a first transfer portion D41, a second bridging portion 42, a third bridging portion 43, a fourth bridging portion 44, a fifth bridging portion 45, and a sixth bridging portion 46. In some embodiments, some repeating units are provided with first bridging portions 41 correspondingly, and some repeating units are provided with first transfer portions D41 correspondingly. The orthographic projection of the first transfer portion D41 on the base substrate is located between the orthographic projections of two first signal connection lines Ls1 adjacent in the first direction X on the base substrate, and the orthographic projection of the first transfer portion D41 on the base substrate is located between the orthographic projections of two adjacent first signal lines L1 on the base substrate. The structure of the first bridging portion 41 and the structure of the first transfer portion D41 are slightly different from each other. The first bridging portion 41 includes a first connection portion 41x and two protruding portions 41t connected to the first connection portion 41x. The orthographic projection of the first connection portion 41x on the base substrate extends in the second direction Y, and is located between orthographic projections of the two protruding portions 41t on the base substrate. The first transfer portion D41 includes a second connection portion 41y and a protruding portion 41t connected to the second connection portion 41y. The orthographic projection of the second connection portion 41y on the base substrate extends in the second direction Y. The first connection portion 41x in the first bridging portion 41 and the second connection portion 41y in the first transfer portion D41 are respectively connected to the third connection portion 23 and the ninth active portion 79 in the corresponding pixel driving circuit through via holes, so as to be connected to the first electrode of the fifth transistor and the second electrode of the capacitor C. The second bridging portion 42 may be connected to the tenth active portion 710 through a via hole, so as to be connected to the second electrode of the sixth transistor T6 and the second electrode of the seventh transistor T7. The third bridging portion 43 may be connected to the eleventh active portion 711 and the sixteenth active portion 816 respectively through via holes, so as to be connected to the second electrode of the second transistor T2, the first electrode of the sixth transistor T6, and the second electrode of the driving transistor T3. The fourth bridging portion 44 may be connected to the fifteenth active portion 815 and the first conductive portion 11 respectively through via holes, so as to be connected to the first electrode of the second transistor T2 and the gate of the driving transistor. An opening 221 is formed on the second conductive portion 22, and the orthographic projection of the via hole connected between the first conductive portion 11 and the fourth bridging portion 44 on the base substrate is located within the orthographic projection of the opening 221 on the base substrate, so as to insulate the via hole from the second conductive portion 22. The fifth bridging portion 45 may be connected to the twelfth active portion 712 through a via hole, so as to be connected to the first electrode of the fourth transistor. The sixth bridging portion 46 may be connected to the fourteenth active portion 814 and the first initial signal line Vinit1 respectively through via holes, so as to be connected to the first electrode of the first transistor and the first initial signal end. In some embodiments, in repeating units adjacent in the first direction X, two adjacent pixel driving circuits may share a same sixth bridging portion 46. The first signal line L1 may be connected to the thirteenth active portion 713 through a via hole, so as to be connected to the first electrode of the seventh transistor and the second initial signal end.

As shown in FIG. 12, FIG. 19, and FIG. 27, the orthographic projection of the first signal connection line Ls1 on the base substrate and the orthographic projection of the eighth active portion 78 on the base substrate at least partially overlap with each other. According to such arrangement, overlapping between the first signal connection line Ls1 and the equipotential structure of the second electrode of the driving transistor T3 located in the first active layer may be avoided, thus improving the residual image problem of the display panel.

As shown in FIG. 12, FIG. 20, and FIG. 28, the fifth conductive layer may include the second signal line L2, the plurality of data lines Da, and the seventh bridging portion 57 mentioned above. The second signal line L2 includes two power lines VDD extending in parallel in the second direction Y and connected to each other. The orthographic projections of the data lines Da on the base substrate may all extend in the second direction Y. The power line VDD may be configured to provide the first power end in FIG. 10, and the data line Da may be configured to provide the data signal end in FIG. 10. Each column of pixel driving circuits may be correspondingly provided with a power line VDD, and the power line VDD may be connected to the first bridging portion 41 through a via hole, so as to be connected to the first electrode of the fifth transistor and the first power end. The data line Da may be connected to the fifth bridging portion 45 through a via hole, so as to be connected to the first electrode of the fourth transistor and the data signal end. The seventh bridging portion 57 may be connected to the second bridging portion 42 through a via hole, so as to be connected to the second electrode of the seventh transistor. In repeating units adjacent in the first direction, adjacent power lines VDD are connected to each other. The power lines VDD may form a grid structure through the first bridging portion 41. By using the power line of the grid structure, the voltage drop of the power signal on the power line may be reduced.

As shown in FIG. 12, FIG. 20, and FIG. 28, the power line VDD may include a first power line segment VDD1, a second power line segment VDD2, a third power line segment VDD3. The second power line segment VDD2 is connected between the first power line segment VDD1 and the third power line segment VDD3. The size in the first direction X of the orthographic projection of the second power line segment VDD2 on the base substrate may be greater than the size in the first direction X of the orthographic projection of the first power line segment VDD1 on the base substrate, and the size in the first direction X of the orthographic projection of the second power line segment VDD2 on the base substrate may be greater than the size in the first direction X of the orthographic projection of the third power line segment VDD3 on the base substrate. In addition, the orthographic projection of the second power line segment VDD2 on the base substrate may further cover the orthographic projection of the first active portion 81 on the base substrate and the orthographic projection of the second active portion 82 on the base substrate. The second power line segment VDD2 may be configured to reduce the influence of light on the characteristics of the first transistor T1 and the second transistor T2. The orthographic projection of the power line VDD on the base substrate may further at least partially overlap with the orthographic projection of the fourth bridging portion 44 on the base substrate, and the power line VDD may be configured to shield the noise interference of other signals on the fourth bridging portion 44, thus improving the stability of the gate voltage of the driving transistor T3.

As shown in FIG. 12, FIG. 19, FIG. 20, FIG. 27, and FIG. 28, the orthographic projection of the first connection portion 41x on the base substrate is located between orthographic projections of two adjacent data lines Da on the base substrate. The orthographic projection of the second connection portion 41y on the base substrate is located between orthographic projections of two adjacent data lines Da on the base substrate. According to such arrangement, overlapping between the orthographic projection of the data line Da on the base substrate and the orthographic projections of the first connection portion 41x and the second connection portion 41y on the base substrate may be avoided, thus reducing the parasitic capacitance of the data line Da. By using the data line Da with a smaller parasitic capacitance, the charging speed of the data signal on the data line Da may be improved, so as to ensure that the data signal may be fully written into the data signal end of each pixel driving circuit in a shorter scanning period, thus improving the accuracy of the output current of the driving transistor.

As shown in FIG. 12 and FIG. 21, the electrode layer may include a plurality of electrode portions. The plurality of electrode portions may include a first electrode portion R, a second electrode portion G1, a third electrode portion B, and a fourth electrode portion G2. The electrode portion may be connected to the seventh bridging portion 57 through a via hole. As shown in FIG. 12 and FIG. 21, the electrode layer includes a plurality of electrode blocks, a partial structure of the electrode block forms an electrode portion, and other structures of the electrode block may form an epitaxial portion of the electrode portion and a connection portion connected to the electrode portion and the seventh bridging portion 57. In the plurality of electrode portions connected to the same row of pixel driving circuits, the first electrode portion R, the second electrode portion G1, the third electrode portion B and the fourth electrode portion G2 are sequentially and alternately distributed in the row direction. In two adjacent columns of pixel driving circuits, the first electrode portion R and the third electrode portion B are connected to the same column of pixel driving circuits, and the first electrode portion R and the third electrode portion B connected to the same column of pixel driving circuits are sequentially and alternately distributed in the column direction; the second electrode portion G1 and the fourth electrode portion G2 are connected to another column of pixel driving circuits, and the second electrode portion G1 and the fourth electrode portion G2 connected to the same column of pixel driving circuits are sequentially and alternately distributed in the column direction. A plurality of pixel openings PH are formed on the pixel definition layer, and a light-emitting unit is formed within a pixel opening. The plurality of pixel openings PH and the plurality of electrode portions are provided in a one-to-one correspondence. The orthographic projection of the electrode portion on the base substrate coincides with the orthographic projection of the corresponding pixel opening on the base substrate. In some embodiments, the first electrode portion R is configured to form the first electrode of the red light-emitting unit, the second electrode portion G1 and the fourth electrode portion G2 are configured to form the first electrode of the green light-emitting unit, and the third electrode portion B is configured to form the first electrode of the blue light-emitting unit.

As shown in FIG. 12 and FIG. 21, in the adjacent power lines VDD, the power line VDD corresponding to the pixel driving circuit connected to the first electrode portion R is connected to the power line VDD corresponding to the pixel driving circuit connected to the fourth electrode portion G2, to form the second signal line L2. The power line VDD corresponding to the pixel driving circuit connected to the second electrode portion G1 is connected to the power line VDD corresponding to the pixel driving circuit connected to the third electrode portion B, to form the second signal line L2. The pixel driving circuit connected to the first electrode portion R is correspondingly provided with the first signal connection line Ls1. In the correspondingly provided pixel driving circuit and the first signal connection line Ls1, the orthographic projection of the first signal connection line Ls1 on the base substrate is located on a side of the orthographic projection of the data line Da on the base substrate facing the orthographic projection of the power line VDD on the base substrate. The pixel driving circuit connected to the third electrode portion B and the fourth electrode portion G2 is correspondingly provided with the first bridging portion 41, and the first bridging portion 41 is connected between two power lines in the pixel driving circuit corresponding to the first bridging portion 41.

As shown in FIG. 12, FIG. 19, FIG. 20, FIG. 21, FIG. 27, and FIG. 28, the pixel driving circuit connected to the first electrode portion R and the second electrode portion G1 is correspondingly provided with the first transfer portion D41. The first transfer portion D41 is connected to a corresponding pixel driving circuit. The first transfer portion D41 is connected to a power line VDD in a pixel driving circuit connected to the first electrode portion G1 corresponding to the first transfer portion D41 through the protruding portion 41t.

As shown in FIG. 12, FIG. 19, FIG. 20, FIG. 21, FIG. 27, and FIG. 28, the orthographic projection of the first signal connection line Ls1 on the base substrate does not overlap with the orthographic projection of any electrode portion on the base substrate. According to such arrangement, the color shift caused by partial protrusion of the electrode portion may be improved.

As shown in FIG. 12, FIG. 19, FIG. 20, FIG. 21, FIG. 27, and FIG. 28, the first electrode portion R includes a first side edge R1. The extension direction of the orthographic projection of the first side edge R1 on the base substrate intersects with the second direction Y. The first signal connection line Ls1 may include a first line sub-segment Ls11 and a second line sub-segment Ls12. The orthographic projection of the first line sub-segment Ls11 on the base substrate is parallel to the orthographic projection of the first side edge R1 on the base substrate. The second line sub-segment Ls12 is connected to the first line sub-segment Ls11, and the extension direction of the orthographic projection of the second line sub-segment Ls12 on the base substrate is parallel to the second direction Y. That is, the first signal connection line Ls1 avoids the first electrode portion R through the bent first line sub-segment Ls11, so as to prevent the first signal connection line Ls1 from overlapping with the first electrode portion R.

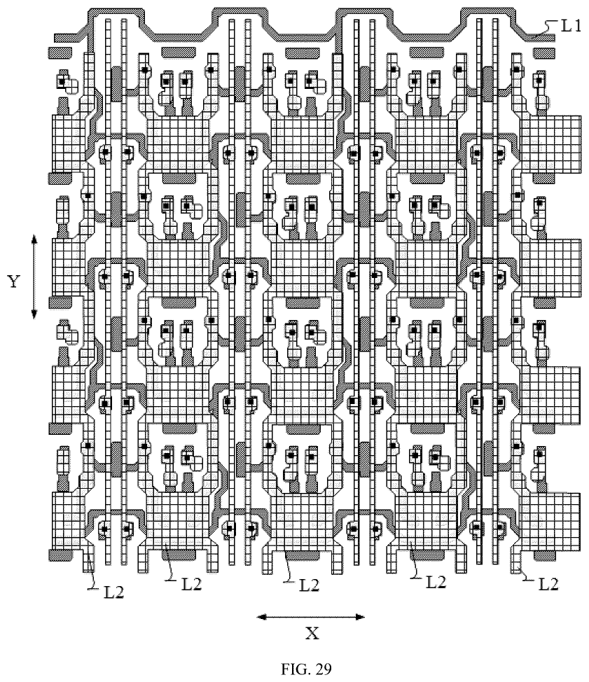

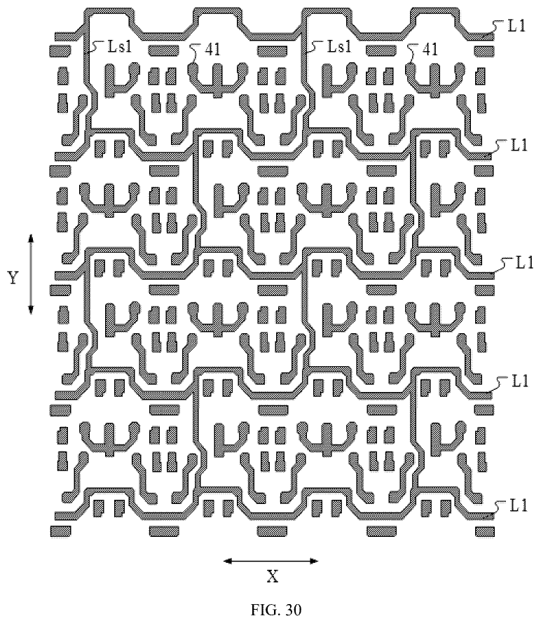

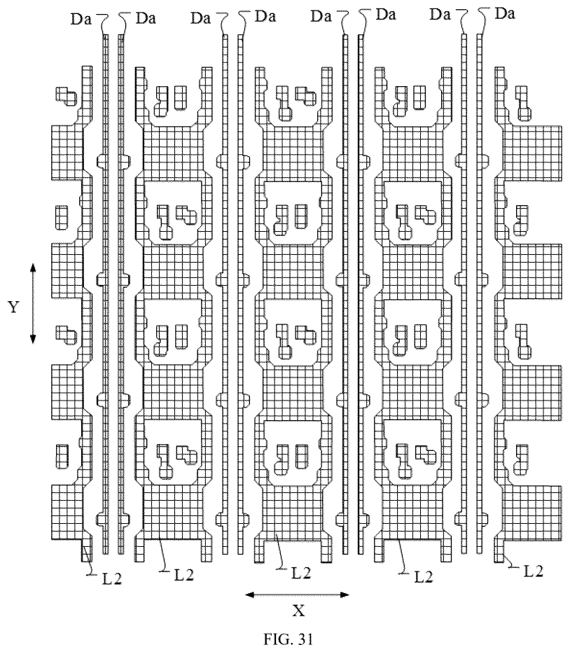

As shown in FIG. 29 to FIG. 31, FIG. 29 is a structural layout of a display panel according to some embodiments of the present disclosure, FIG. 30 is a structural layout of the fourth conductive layer in FIG. 29, and FIG. 31 is a structural layout of the fifth conductive layer in FIG. 29. The partial layout structure of the display panel (all film layer structures being not shown) shown in FIG. 29 includes the partial layout structure of the display panel shown in FIG. 12 distributed in a two-by-two array. It may be clearly seen from FIG. 29 to FIG. 31 that the first signal line L1 forms a grid structure through the first signal connection line Ls1, and the second signal line L2 forms a grid structure through the first bridging portion 41.

It should be noted that, as shown in FIG. 12, FIG. 27, FIG. 28, and FIG. 29, the black block shown on the side of the fourth conductive layer away from the base substrate represents the via hole through which the fourth conductive layer is connected to other layers facing the base substrate side. The black block shown on the side of the fifth conductive layer away from the base substrate represents the via hole through which the fifth conductive layer is connected to other layers facing the base substrate side. The black block shown on the side of the electrode layer away from the base substrate represents the via hole through which the electrode layer is connected to other layers facing the base substrate side. The black block only represents the position of the via hole, and different via holes represented by black blocks at different positions may penetrate through different insulating layers.

FIG. 32 is a partial cross-sectional view of the display panel shown in FIG. 12 along a broken line AA. The display panel may further include a first insulating layer 91, a second insulating layer 92, a third insulating layer 93, a fourth insulating layer 94, a fifth insulating layer 95, a first dielectric layer 96, a passivation layer 97, a first planarization layer 98, a second planarization layer 99. In some embodiments, the base substrate 90, the shielding layer, the first insulating layer 91, the first active layer, the second insulating layer 92, the first conductive layer, the third insulating layer 92, the second conductive layer, the fourth insulating layer 94, the second active layer, the fifth insulating layer 95, the third conductive layer, the first dielectric layer 96, the fourth conductive layer, the passivation layer 97, the first planarization layer 98, the fifth conductive layer, the second planarization layer 99, and the electrode layer are sequentially stacked. The first insulating layer 91, the second insulating layer 92, the third insulating layer 93, the fourth insulating layer 94, and the fifth insulating layer 95 may be of single-layer structures or multi-layer structures. The material of the first insulating layer 91, the second insulating layer 92, the third insulating layer 93, the fourth insulating layer 94, and the fifth insulating layer 95 may be at least one of silicon nitride, silicon oxide, and silicon oxynitride. The first dielectric layer 96 may be a silicon nitride layer. The material of the first planarization layer 98 and the second planarization layer 99 may be an organic material, such as polyimide (PI), polyethylene terephthalate (PET), polyethylene naphthalate (PEN), silicon on glass (SOG), or the like. The passivation layer 97 may be a silicon oxide layer. The base substrate 90 may include a glass substrate, a barrier layer, and a polyimide layer stacked in sequence, and the barrier layer may be an inorganic material. The material of the first conductive layer, the second conductive layer, and the third conductive layer may be one of molybdenum, aluminum, copper, titanium, niobium, or an alloy, or a conductive layer such as a molybdenum/titanium alloy or lamination. The material of the fourth conductive layer and the fifth conductive layer may include a metal material, for example, may be one of molybdenum, aluminum, copper, titanium, niobium, or an alloy, or a molybdenum/titanium alloy or lamination, or a conductive layer such as a titanium/aluminum/titanium lamination. The sheet resistance of any one of the fourth conductive layer and the fifth conductive layer may be less than the sheet resistance of any one of the first conductive layer, the second conductive layer, and the third conductive layer.

In some embodiments, there may be a process error in the manufacturing process of the capacitor C, which causes a fluctuation of the output current of the pixel driving circuit relative to the standard value. It can be seen from the simulation that, when different capacitance design values fluctuate between −5 fF and +5 fF, the fluctuations of the current output by the pixel driving circuit are different. For example, in the 8 grayscale driving environment, the capacitance design value is (C1−10)fF, where: when the fluctuation of the capacitance actual value is −5 fF, the fluctuation of the current output by the red pixel driving circuit is 41.91%, the fluctuation of the current output by the blue pixel driving circuit is 47.62%, and the fluctuation of the current output by the green pixel driving circuit is 54.41%; and when the fluctuation of the capacitance actual value is 5 fF, the fluctuation of the current output by the red pixel driving circuit is −35.55%, the fluctuation of the current output by the blue pixel driving circuit is −40.61%, and the fluctuation of the current output by the green pixel driving circuit is −44.04%. In the 8 grayscale driving environment, the capacitance design value is C1fF, where: when the fluctuation of the capacitance actual value is −5 fF, the fluctuation of the current output by the red pixel driving circuit is 41.58%, the fluctuation of the current output by the blue pixel driving circuit is 45.83%, and the fluctuation of the current output by the green pixel driving circuit is 50.45%; and when the fluctuation of the capacitance actual value is 5 fF, the fluctuation of the current output by the red pixel driving circuit is −35.51%, the fluctuation of the current output by the blue pixel driving circuit is −39.38%, and the fluctuation of the current output by the green pixel driving circuit is −42.04%. In the 8 grayscale driving environment, the capacitance design value is (C1+10)fF, where: when the fluctuation of the capacitance actual value is −5 fF, the fluctuation of the current output by the red pixel driving circuit is 39.73%, the fluctuation of the current output by the blue pixel driving circuit is 42.58%, and the fluctuation of the current output by the green pixel driving circuit is 50.66%; and when the fluctuation of the capacitance actual value is 5 fF, the fluctuation of the current output by the red pixel driving circuit is −34.31%, the fluctuation of the current output by the blue pixel driving circuit is −37.01%, and the fluctuation of the current output by the green pixel driving circuit is −42.52%. It can be seen from the above data that, the greater the capacitance value of the capacitor C, the smaller the fluctuation of the current output by the pixel driving circuit. The reason is that, the greater the capacitance value of the capacitor C, the stronger the voltage stabilization effect of the capacitor C on the gate of the driving transistor, and the smaller the fluctuation of the current output by the driving transistor. In some embodiments, the capacitance value of the capacitor C may be designed as great as possible to reduce the fluctuation of the current output by the pixel driving circuit. For example, it may be increased by 2%-10% based on the original design value of the capacitor C.

It should be noted that the scale of the drawings in the present disclosure may be used as a reference in the actual process, which is not limited to this. For example, the width-to-length ratio of the channel, the thickness of each film layer, the spacing between each film layer, the width of each signal line, and the spacing between each signal line may be adjusted according to actual needs. The quantity of pixels in the display substrate and the quantity of sub-pixels in each pixel are not limited to the quantity shown in the drawings, and the drawings described in the present disclosure are merely schematic structural diagrams. In addition, terms such as “first” and “second” are only configured to define different structural names, and do not mean a specific order. The same structural layer may be formed by a same patterning process. In some embodiments, the orthographic projection of a structure on the base substrate extending in a certain direction, may be understood as that the orthographic projection of the structure on the base substrate extends linearly or in a bent manner in the direction.

According to embodiments of the present disclosure, there is further provided a display device, including the above display panel. The display device may be a display device such as a mobile phone, a tablet computer, and a television, etc.

Other embodiments of the present disclosure will be apparent to those skilled in the art from consideration of the description and practice of the present disclosure disclosed herein. The present application is intended to cover any variations, uses, or adaptations of the present disclosure following the general principles of the present disclosure and including common general knowledge and conventional technical means in the art not disclosed in the present disclosure. It is intended that the description and examples be considered as exemplary only, with a true scope and spirit of the present disclosure being indicated by the following claims.

It should be understood that the present disclosure is not limited to the precise structures that have been described above and shown in the accompanying drawings, and various modifications and changes may be made without departing from the scope of the present disclosure. The scope of the present disclosure is defined only by the appended claims.

1. A display panel, comprising:
a base substrate;
a plurality of first signal lines, wherein orthographic projections of the plurality of first signal lines on the base substrate extend in a first direction and are distributed at intervals in a second direction, and the first direction intersects with the second direction;
a plurality of first signal connection lines, wherein an orthographic projection of a first signal connection line on the base substrate extends in the second direction, and the first signal connection line is connected between two first signal lines adjacent in the second direction to form a grid structure with the first signal lines;
a plurality of second signal lines, wherein the second signal lines are located in a different conductive layer from the first signal lines, and orthographic projections of the plurality of second signal lines on the base substrate extend in the second direction and are distributed at intervals in the first direction; and
a plurality of first bridging portions, wherein a first bridging portion is connected between two second signal lines adjacent in the first direction to form a grid structure with the second signal lines;
wherein an orthographic projection of the first bridging portion on the base substrate is located between orthographic projections of two first signal connection lines adjacent in the first direction on the base substrate, and the orthographic projection of the first bridging portion on the base substrate is located between orthographic projections of two adjacent first signal lines on the base substrate.

2. The display panel according to claim 1, wherein two adjacent first signal connection lines and two adjacent first signal lines connected to the two adjacent first signal connection lines form an annular structure; and, a plurality of annular structures comprise a first annular structure, a second annular structure, and a third annular structure;
the first annular structure and the second annular structure are distributed in the first direction, the first annular structure and the third annular structure are distributed in the second direction, and the first annular structure and the third annular structure are provided in a staggered manner in the first direction;
the second annular structure and the third annular structure are distributed in the second direction, and the second annular structure and the third annular structure are provided in a staggered manner in the first direction;
the first bridging portion whose orthographic projection on the base substrate being located within one of the annular structures forms a bridging portion group;
a plurality of bridging portion groups comprises a first bridging portion group, a second bridging portion group, and a third bridging portion group; an orthographic projection of the first bridging portion group on the base substrate is located within an orthographic projection of the first annular structure on the base substrate, an orthographic projection of the second bridging portion group on the base substrate is located within an orthographic projection of the second annular structure on the base substrate, and an orthographic projection of the third bridging portion group on the base substrate is located within an orthographic projection of the third annular structure on the base substrate; and
the first bridging portion group and the second bridging portion group are respectively connected to different second signal lines, the first bridging portion group and the third bridging portion group are connected to at least one same second signal line, and the second bridging portion group and the third bridging portion group are connected to at least one same second signal line.

3. The display panel according to claim 2, wherein the first annular structure and the second annular structure share a same first signal connection line, the first annular structure and the third annular structure share a partial structure of a same first signal line, and the second annular structure and the third annular structure share a partial structure of a same first signal line.

4. The display panel according to claim 2, wherein,
a distance in the first direction between orthographic projections of two first signal connection lines in each of the annular structures on the base substrate is the same or approximately the same, and each bridging portion group comprises a same quantity of first bridging portions.

5. The display panel according to claim 2, wherein a first bridging portion in the first bridging portion group comprises a first bridging sub-portion, a first bridging portion in the second bridging portion group comprises a second bridging sub-portion, and a first bridging portion in the third bridging portion group comprises a third bridging sub-portion;
in the first direction, an orthographic projection of the third bridging sub-portion on the base substrate is located between an orthographic projection of the first bridging sub-portion on the base substrate and an orthographic projection of the second bridging sub-portion on the base substrate; and
the orthographic projection of the first bridging sub-portion on the base substrate and the orthographic projection of the second bridging sub-portion on the base substrate are provided adjacent in the first direction, and an orthographic projection of the first signal connection line on the base substrate is located between the orthographic projection of the first bridging sub-portion on the base substrate and the orthographic projection of the second bridging sub-portion on the base substrate.

6. The display panel according to claim 2, wherein the bridging portion group comprises a first bridging portion, the first signal connection lines connected between adjacent first signal lines in a same group form a first signal connection line row, and the first bridging portions located between the adjacent first signal lines in a same group form a first bridging portion row;
in first signal connection line rows adjacent in the second direction, orthographic projections of the first signal connection lines located in different first signal connection line rows on the base substrate are sequentially and alternately distributed in the first direction; and
in first bridging portion rows adjacent in the second direction, orthographic projections of the first bridging portions located in different first bridging portions rows on the base substrate are sequentially and alternately distributed in the first direction.

7. The display panel according to claim 6, wherein orthographic projections of the first signal connection lines located in a same first signal connection line row on the base substrate are distributed at equal intervals or approximately equal intervals in the first direction; and
orthographic projections of the first bridging portions located in a same first bridging portion row on the base substrate are distributed at equal intervals or approximately equal intervals in the first direction.

8. The display panel according to claim 1, wherein the display panel comprises a light-emitting unit, a power line, and pixel driving circuits distributed in an array in the first direction and the second direction; a pixel driving circuit is connected to a first electrode of the light-emitting unit, the power line is configured to provide a high-level power signal to the pixel driving circuit, the second direction is a column direction, and each column of pixel driving circuits is correspondingly provided with a power line;
wherein the display panel further comprises:
an electrode layer, located on a side of the base substrate, wherein the electrode layer comprises a plurality of electrode portions, and an electrode portion is configured to form the first electrode of the light-emitting unit; and
a pixel definition layer, located on a side of the electrode layer away from the base substrate, wherein a plurality of pixel openings are formed on the pixel definition layer, the pixel openings and the electrode portions are correspondingly provided, and an orthographic projection of a pixel opening on the base substrate coincides with an orthographic projection of an electrode portion corresponding to the pixel opening on the base substrate;
wherein, the plurality of electrode portions comprise a first electrode portion, a second electrode portion, a third electrode portion and a fourth electrode portion; and in a plurality of electrode portions connected to a same row of pixel driving circuits, the first electrode portion, the second electrode portion, the third electrode portion and the fourth electrode portion are sequentially and alternately distributed in a row direction;
an orthographic projection of the power line on the base substrate extends in the second direction; in adjacent power lines, a power line corresponding to a pixel driving circuit connected to the first electrode portion is connected to a power line corresponding to a pixel driving circuit connected to the fourth electrode portion to form a second signal line; and, a power line corresponding to a pixel driving circuit connected to the second electrode portion is connected to a power line corresponding to a pixel driving circuit connected to the third electrode portion to form a second signal line; and
the pixel driving circuit connected to the first electrode portion is correspondingly provided with a first signal connection line, the pixel driving circuit connected to the third electrode portion and the fourth electrode portion is correspondingly provided with a first bridging portion, and the first bridging portion is connected between two power lines in the pixel driving circuit corresponding to the first bridging portion.

9. The display panel according to claim 8, wherein the first electrode portion is configured to form a first electrode of a red light-emitting unit, the second electrode portion and the fourth electrode portion are configured to form a first electrode of a green light-emitting unit, and the third electrode portion is configured to form a first electrode of a blue light-emitting unit.

10. The display panel according to claim 8, further comprising:
a data line, wherein an orthographic projection of the data line on the base substrate extends in the second direction, and the data line is configured to provide a data signal to the pixel driving circuit;
wherein, in the pixel driving circuit and the first signal connection line that are provided correspondingly, an orthographic projection of the first signal connection line on the base substrate is located on a side of the orthographic projection of the data line on the base substrate facing an orthographic projection of the power line on the base substrate.

11. The display panel according to claim 8, further comprising:
a first transfer portion, located on a same conductive layer as the first bridging portion, wherein an orthographic projection of the first transfer portion on the base substrate is located between orthographic projections of two first signal connection lines adjacent in the first direction on the base substrate, and the orthographic projection of the first transfer portion on the base substrate is located between orthographic projections of two adjacent first signal lines on the base substrate;
wherein, the pixel driving circuit connected to the first electrode portion and the second electrode portion is correspondingly provided with the first transfer portion, the first transfer portion is connected to the pixel driving circuit corresponding to the first transfer portion, and the first transfer portion is connected to the power line in the pixel driving circuit connected to the second electrode portion corresponding to the first transfer portion.

12. The display panel according to claim 11, wherein the first bridging portion is further connected to the pixel driving circuit corresponding to the first bridging portion, and the first bridging portion comprises:
a first connection portion, wherein an orthographic projection of the first connection portion on the base substrate extends in the second direction, and the first connection portion is connected to the pixel driving circuit;
wherein the first transfer portion comprises:
a second connection portion, wherein an orthographic projection of the second connection portion on the base substrate extends in the second direction, and the second connection portion is connected to the pixel driving circuit;
the display panel further comprises:
a data line, wherein an orthographic projection of the data line on the base substrate extends in the second direction, and the data line is configured to provide a data signal to the pixel driving circuit;
wherein the orthographic projection of the first connection portion on the base substrate is located between orthographic projections of two adjacent data lines on the base substrate; and
the orthographic projection of the second connection portion on the base substrate is located between orthographic projections of two adjacent data lines on the base substrate.

13. The display panel according to claim 8, wherein an orthographic projection of the first signal connection line on the base substrate does not overlap with an orthographic projection of the electrode portion on the base substrate.

14. The display panel according to claim 13, wherein the first electrode portion comprises a first side edge, and an extension direction of an orthographic projection of the first side edge on the base substrate intersects with the second direction; and
the first signal connection line comprises:
a first line sub-segment, wherein an orthographic projection of the first line sub-segment on the base substrate is parallel to the orthographic projection of the first side edge on the base substrate; and
a second line sub-segment, connected to the first line sub-segment, wherein an extension direction of an orthographic projection of the second line sub-segment on the base substrate is parallel to the second direction.

15. The display panel according to claim 1, wherein the display panel further comprises a pixel driving circuit, the pixel driving circuit comprises a driving transistor and a fifth transistor, a first electrode of the fifth transistor is connected to a power line, and a second electrode of the fifth transistor is connected to a first electrode of the driving transistor; and
the display panel further comprises:
a first active layer, located on a side of the base substrate, wherein the first active layer comprises a third active portion and a fifth active portion, the third active portion is configured to form a channel region of the driving transistor, and the fifth active portion is configured to form a channel region of the fifth transistor;
wherein an orthographic projection of the first signal connection line on the base substrate is located on a side of an orthographic projection of the third active portion on the base substrate close to an orthographic projection of the fifth active portion on the base substrate.

16. The display panel according to claim 1, wherein the display panel further comprises a light-emitting unit, a pixel driving circuit, a power line and a second initial signal line, the pixel driving circuit is connected to a first electrode of the light-emitting unit, the power line is configured to provide a high-level power signal to the pixel driving circuit, and the second initial signal line is configured to provide an initial signal line to a first electrode of the light-emitting unit; and
a first signal line is configured to form the second initial signal line, and a second signal line is configured to form the power line.

17. The display panel according to claim 1, wherein the first signal lines, the first signal connection lines, the first bridging portions are located in a same conductive layer, and the first signal lines and the first signal connection lines are connected in a same layer; and
the plurality of second signal lines are located in a same conductive layer.

18. The display panel according to claim 1, wherein the display panel comprises a pixel driving circuit and a light-emitting unit; and the pixel driving circuit comprises a driving transistor, a first transistor, a second transistor, a fourth transistor, a fifth transistor, a sixth transistor, a seventh transistor, and a capacitor;
a first electrode of the first transistor is connected to a first initial signal line, and a second electrode of the first transistor is connected to a gate of the driving transistor;
a first electrode of the second transistor is connected to the gate of the driving transistor, and a second electrode of the second transistor is connected to a second electrode of the driving transistor;
a first electrode of the fourth transistor is connected to a data line, and a second electrode of the fourth transistor is connected to a first electrode of the driving transistor;
a first electrode of the fifth transistor is connected to a power line, and a second electrode of the fifth transistor is connected to the first electrode of the driving transistor;
a first electrode of the sixth transistor is connected to the second electrode of the driving transistor, and a second electrode of the sixth transistor is connected to a first electrode of the light-emitting unit;
a first electrode of the seventh transistor is connected to a second initial signal line, and a second electrode of the seventh transistor is connected to the first electrode of the light-emitting unit; and
a first electrode of the capacitor is connected to the gate of the driving transistor, and a second electrode of the capacitor is connected to the power line.

19. A display panel, comprising:
a base substrate;
a plurality of first signal lines, wherein orthographic projections of the plurality of first signal lines on the base substrate extend in a first direction and are distributed at intervals in a second direction, and the first direction intersects with the second direction;
a plurality of first signal connection lines, wherein an orthographic projection of a first signal connection line on the base substrate extends in the second direction, and the first signal connection line is connected between two first signal lines adjacent in the second direction to form a grid structure with the first signal lines;
a plurality of second signal lines, wherein the second signal lines are located in a different conductive layer from the first signal lines, and orthographic projections of the plurality of second signal lines on the base substrate extend in the second direction and are distributed at intervals in the first direction; and
a plurality of first bridging portions, wherein the first bridging portions are configured to be electrically connected to the second signal lines to form a grid structure with the second signal lines;
wherein an orthographic projection of a first bridging portion on the base substrate is located between orthographic projections of two first signal connection lines adjacent in the first direction on the base substrate, and the orthographic projection of the first bridging portion on the base substrate is located between orthographic projections of two adjacent first signal lines on the base substrate.

20. A display device, comprising a display panel, wherein the display panel comprises:
a base substrate;
a plurality of first signal lines, wherein orthographic projections of the plurality of first signal lines on the base substrate extend in a first direction and are distributed at intervals in a second direction, and the first direction intersects with the second direction;
a plurality of first signal connection lines, wherein an orthographic projection of a first signal connection line on the base substrate extends in the second direction, and the first signal connection line is connected between two first signal lines adjacent in the second direction to form a grid structure with the first signal lines;
a plurality of second signal lines, wherein the second signal lines are located in a different conductive layer from the first signal lines, and orthographic projections of the plurality of second signal lines on the base substrate extend in the second direction and are distributed at intervals in the first direction; and
a plurality of first bridging portions, wherein a first bridging portion is connected between two second signal lines adjacent in the first direction to form a grid structure with the second signal lines;
wherein an orthographic projection of the first bridging portion on the base substrate is located between orthographic projections of two first signal connection lines adjacent in the first direction on the base substrate, and the orthographic projection of the first bridging portion on the base substrate is located between orthographic projections of two adjacent first signal lines on the base substrate.
